(19) United States
(12) Patent Application Publication
(10) Pub. No.: US 2024/0250169 A1
(43) Pub. Date: Jul. 25, 2024

(54) SEMICONDUCTOR DEVICE INCLUDING ACTIVE PATTERN

(71) Applicant: SAMSUNG ELECTRONICS CO., LTD., Suwon-si (KR)

(72) Inventors: KYUNGHWAN LEE, Suwon-si (KR); Sanghoon UHM, Suwon-si (KR); Minhee CHO, Suwon-si (KR); Daewon HA, Suwon-si (KR)

(21) Appl. No.: 18/420,969

(22) Filed: Jan. 24, 2024

(30) Foreign Application Priority Data
Jan. 25, 2023 (KR) 10-2023-0009410

(51) Int. Cl. H01L 29/78; H10B 12/00

(52) U.S. Cl. CPC H01L 29/7827; H10B 12/0335; H10B 12/053; H10B 12/34; H10B 12/482

(57) ABSTRACT

A semiconductor device includes an active pattern having a vertical active portion extending in a vertical direction and a first bend portion bent from an upper region of the vertical active portion; a gate electrode spaced apart from the active pattern, wherein at least a portion thereof faces the vertical active portion; an etch stop layer in which at least a portion thereof is disposed between an upper surface of the gate electrode and the first bend portion; a dielectric layer in which at least a portion thereof is disposed between the active pattern and the gate electrode; and a contact plug disposed on the etch stop layer and at least penetrating through the first bend portion.

### CROSS-REFERENCE TO RELATED APPLICATION

This application claims benefit of priority to Korean Patent Application No. 10-2023-0009410, filed on Jan. 25, 2023, in the Korean Intellectual Property Office, the disclosure of which is incorporated herein by reference in its entirety.

### BACKGROUND

### 1. Field

Example embodiments relate to a semiconductor device including an active pattern.

### 2. Description of the Related Art

Research has been conducted to reduce the size of elements constituting a semiconductor device and improve performance. For example, in a dynamic random access memory (DRAM), research is being conducted to reliably and stably form components with a reduced size. However, with a reduction of the size of the components, the dispersion characteristics of semiconductor devices may deteriorate.

### SUMMARY

According to example embodiments, a semiconductor device includes: an active pattern including a vertical active portion extending in a vertical direction and a first bend portion bent from an upper region of the vertical active portion; a gate electrode spaced apart from the active pattern, wherein at least a portion thereof faces the vertical active portion; an etch stop layer in which at least a portion thereof is disposed between an upper surface of the gate electrode and the first bend portion; a dielectric layer in which at least a portion thereof is disposed between the active pattern and the gate electrode; and a contact plug disposed on the etch stop layer and at least penetrating through the first bend portion.

According to example embodiments, a semiconductor device includes a bit line; an active pattern electrically connected to the bit line; a word line disposed on the same level as at least a portion of the active pattern; a dielectric layer in which at least a portion thereof is disposed between the active pattern and the word line; an etch stop layer in which at least a portion thereof is disposed on the same level as a portion of the active pattern; and a contact plug in contact with the etch stop layer on the etch stop layer and electrically connected to the active pattern, wherein a lower surface of the contact plug is disposed on a level higher than a lower surface of the etch stop layer, and an upper end of the active pattern is disposed on a level higher than the lower surface of the etch stop layer.

According to example embodiments, a semiconductor device includes: a bit line; an interlayer insulating layer disposed on the bit line and having an opening; a first gate electrode and a second gate electrode spaced apart from each other, within the opening; an active pattern disposed between the first gate electrode and the second gate electrode and electrically connected to the bit line; a first etch stop layer on the first gate electrode; a second etch stop layer on the second gate electrode; a first dielectric layer in which at least a portion thereof is disposed between the first gate electrode and the active pattern; a second dielectric layer in which at least a portion thereof is disposed between the second gate electrode and the active pattern; and a first contact plug in contact with the first etch stop layer on the first etch stop layer; and a second contact plug in contact with the second etch stop layer on the second etch stop layer.

### BRIEF DESCRIPTION OF DRAWINGS

Features will become apparent to those of skill in the art by describing in detail exemplary embodiments with reference to the attached drawings, in which:

FIGS. 1, 2A, and 2B are views schematically illustrating a semiconductor device according to an example embodiment of the present disclosure;

FIG. 3 is a conceptual cross-sectional view illustrating a modified example of a semiconductor device according to an example embodiment of the present disclosure;

FIG. 4 is a top view schematically illustrating a modified example of a semiconductor device according to an example embodiment of the present disclosure;

FIG. 5 is a conceptual cross-sectional view illustrating a modified example of a semiconductor device according to an example embodiment of the present disclosure;

FIGS. 6, 7A and 7B are views schematically illustrating a modified example of a semiconductor device according to an example embodiment of the present disclosure;

FIG. 8 is a conceptual cross-sectional view illustrating a modified example of a semiconductor device according to an example embodiment of the present disclosure;

FIGS. 9, 10A and 10B are views schematically illustrating a modified example of a semiconductor device according to an example embodiment of the present disclosure;

FIG. 11 is a conceptual cross-sectional view illustrating a modified example of a semiconductor device according to an example embodiment of the present disclosure;

FIG. 12 is a conceptual cross-sectional view illustrating a modified example of a semiconductor device according to an example embodiment of the present disclosure;

FIGS. 13, 14A and 14B are views schematically illustrating a modified example of a semiconductor device according to an example embodiment of the present disclosure;

FIG. 15A is a conceptual cross-sectional view illustrating a modified example of a semiconductor device according to an example embodiment of the present disclosure;

FIG. 15B is a conceptual cross-sectional view illustrating a modified example of a semiconductor device according to an example embodiment of the present disclosure;

FIG. 15C is a conceptual perspective view illustrating an example of a semiconductor device according to an example embodiment of the present disclosure;

FIG. 15D is a conceptual cross-sectional view illustrating bonding between the stacked chips illustrated in FIG. 15C;

FIGS. 16 to 21B are views schematically illustrating stages in a method of forming a semiconductor device according to an example embodiment of the present disclosure; and

FIGS. 22 to 26B are views schematically illustrating stages in method of forming a semiconductor device according to an example embodiment of the present disclosure.

### DETAILED DESCRIPTION

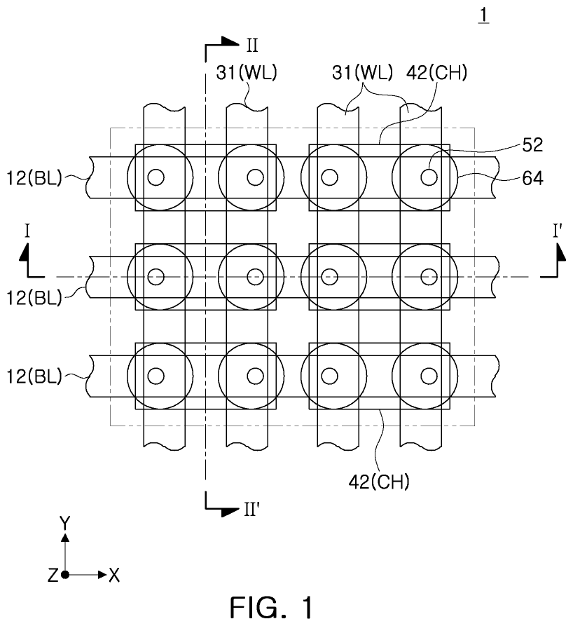

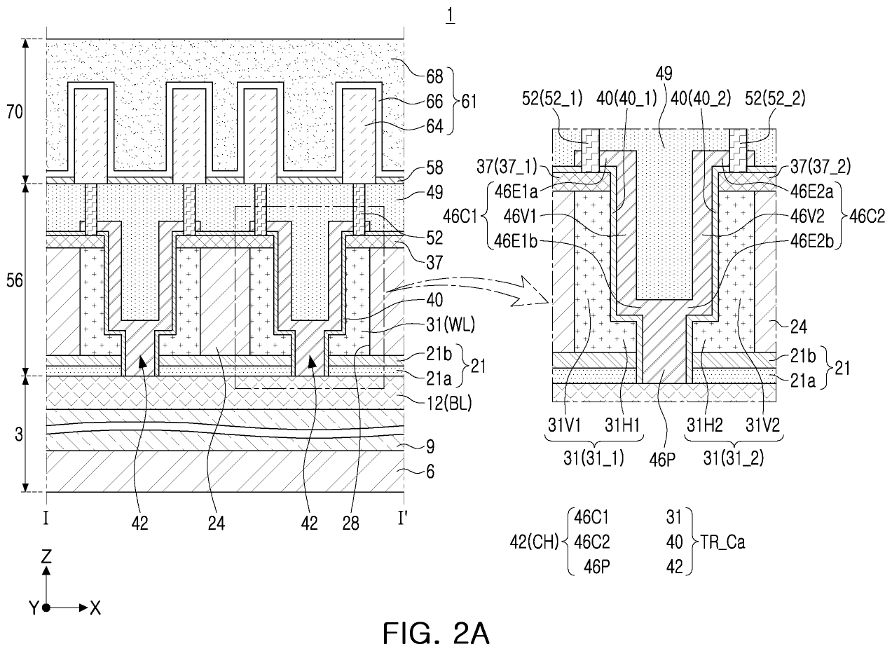

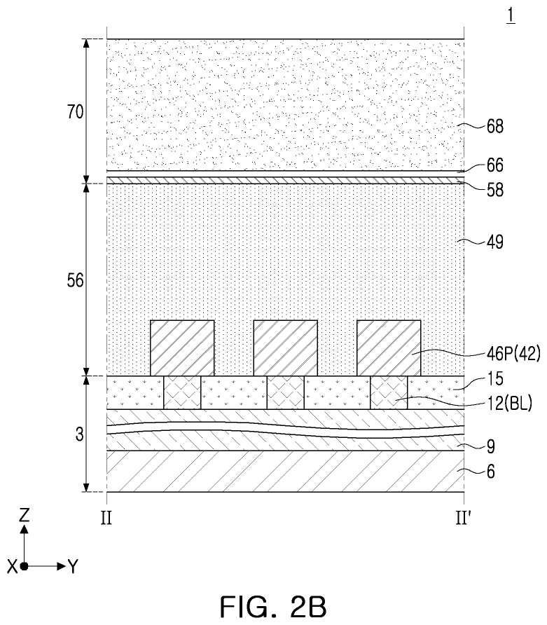

Exemplary embodiments of a semiconductor device will be described with reference to FIGS. 1, 2A and 2B. In FIGS. 1 to 2B, FIG. 1 is a top view schematically illustrating a semiconductor device according to an example embodiment of the present disclosure, FIG. 2A is a cross-sectional view along line I-I′ of FIG. 1, and FIG. 2B is a cross-sectional view along line II-II′ of FIG. 1.

Referring to FIGS. 1, 2A and 2B, a semiconductor device 1 according to an example embodiment may include a first structure 3, a second structure 56 disposed on the first structure 3, and a third structure 70 disposed on the second structure 56. For example, as illustrated in FIG. 2A, the second structure 56 may be between the first structure 3 and the third structure 70 in the vertical direction (Z-direction).

The first structure 3 may include conductive lines 12. Each of the conductive lines 12 may have a line shape extending in a first direction (X-direction). The conductive lines 12 may be bit lines BL. Hereinafter, components referred to with reference character “BL” may be understood as bit lines even if there is no separate description thereof.

Each of the conductive lines 12 may include, e.g., doped polysilicon, a metal, a conductive metal nitride, a metal-semiconductor compound, a conductive metal oxide, conductive graphene, carbon nanotubes, or combinations thereof. For example, each of the conductive lines 12 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, graphene, carbon nanotubes or combinations thereof. Each of the conductive lines 12 may include a single layer or multiple layers of the materials described above.

The first structure 3 may further include a base 6, a lower insulating layer 9 disposed on the base 6, and intermetallic insulating layers 15 between the conductive lines 12. For example, as illustrated in FIG. 2B, the intermetallic insulating layers 15 and the conductive lines 12 may alternate in the second direction (Y direction) on the lower insulating layer 9.

The base 6 may be a semiconductor substrate. For example, the base 6 may include a Group IV semiconductor, a Group III-V compound semiconductor, or a Group II-VI compound semiconductor. The substrate may be a substrate including at least one of, e.g., silicon, silicon carbide, germanium, and silicon-germanium. For example, the base 6 may include a silicon material, e.g., a single crystal silicon material. The conductive lines 12 and the intermetallic insulating layers 15 may be disposed on the lower insulating layer 9.

The second structure 56 may include at least one buffer insulating layer 21, an interlayer insulating layer 24, gate electrodes 31, dielectric layers 40, active patterns 42, and an etch stop layer 37.

The at least one buffer insulating layer 21 may be disposed on the first structure 3. For example, the at least one buffer insulating layer 21 may include a first buffer insulating layer 21a and a second buffer insulating layer 21b which are sequentially stacked, e.g., directly on the first structure 3. The first and second buffer insulating layers 21a and 21b may include different insulating materials. For example, one of the first and second buffer insulating layers 21a and 21b may include silicon nitride, and the other thereof may include a metal oxide, e.g., aluminum oxide. The first and second buffer insulating layers 21a and 21b may be formed of an insulating material having etching selectivity with a material of the interlayer insulating layer 24. The interlayer insulating layer 24 may include, e.g., silicon oxide or a low-κ dielectric.

The gate electrodes 31 may be disposed on the at least one buffer insulating layer 21. The gate electrodes 31 may be word lines WL. Hereinafter, components referred to with reference characters “WL” may be understood as word lines even if there is no separate description thereof.

In the top view, as illustrated in FIG. 1, each of the gate electrodes 31 may extend in the second direction (Y-direction). The second direction (Y-direction) may be perpendicular to the first direction (X-direction). Each of the gate electrodes 31 may include, e.g., doped polysilicon, a metal, a conductive metal nitride, a metal-semiconductor compound, a conductive metal oxide, conductive graphene, carbon nanotubes, or combinations thereof. For example, each of the gate electrodes 31 may be made of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, graphene, carbon nanotubes, or combinations thereof. Each of the gate electrodes 31 may include a single layer or multiple layers of the materials described above.

The interlayer insulating layer 24 may have openings 28. A pair of gate electrodes 31 may be disposed in one of the openings 28. In one (e.g., single) opening 28, the pair of gate electrodes 31 may include a first gate electrode 31_1 and a second gate electrode 31_2 which are spaced apart from each other, e.g., in the first direction (X direction).

In the enlarged cross-sectional structure illustrated in FIG. 2A, the first gate electrode 31_1 may include a first vertical gate portion 31V1 extending in the vertical direction (Z-direction) and a first horizontal gate portion 31H1 extending in a direction oriented from a lower region of the first vertical gate portion 31V1 toward the second gate electrode 31_2 (e.g., to have an L-shaped vertical cross-section), and the second gate electrode 31_2 may include a second vertical gate portion 31V2 extending in the vertical direction (Z-direction) and a second horizontal gate portion 31H2 extending in a direction oriented from a lower region of the second vertical gate portion 31V2 toward the first gate electrode 31_1 (e.g., to have a sideways inverted L-shaped vertical cross-section).

The active pattern 42 may be positioned within one opening 28 between the first and second gate electrodes 31_1 And 31_2. The active pattern 42 may include a region vertically overlapping the first horizontal gate portion 31H1 and a region vertically overlapping the second horizontal gate portion 31H2.

The active patterns 42 may include a material that may be used as a channel of a transistor, e.g., a semiconductor material. For example, each of the active patterns 42 may be formed of a semiconductor material, e.g., silicon (Si) or silicon germanium (SiGe). For example, each of the active patterns 42 may be formed of single crystalline silicon or polysilicon. However, each of the active patterns 42 is not limited to semiconductor materials, e.g., each of the active patterns 42 may include at least one oxide semiconductor layer or at least one two-dimensional material layer that may be used as a channel region of a transistor.

For example, the oxide semiconductor layer may be indium gallium zinc oxide (IGZO). In another example, the oxide semiconductor layer may include at least one of indium tungsten oxide (IWO), indium tin gallium oxide (ITGO), indium aluminum zinc oxide (IAGO), indium gallium oxide (IGO), indium tin zinc oxide (ITZO), zinc tin oxide (ZTO or ZnSnO), indium zinc oxide (IZO or InZnO), ZnO, indium gallium silicon oxide (IGSO or InGaSiO), indium oxide (InO), tin oxide (SnO), titanium oxide (TiO), magnesium zinc oxide (MgZnO), indium gallium zinc oxide (InGaZnO), zirconium indium zinc oxide (ZrInZnO), hafnium indium zinc oxide (HfInZnO), tin indium zinc oxide (SnInZnO), aluminum tin indium zinc oxide (AlSnInZnO), silicon indium zinc oxide (SiInZnO), aluminum zinc tin oxide (AlZnSnO), gallium zinc tin oxide (GaZnSnO), and zirconium zinc tin oxide (ZrZnSnO).

For example, the two-dimensional material layer may include at least one of a transition metal dichalcogenide material layer (TMD material layer), a black phosphorous material layer, and a hexagonal Boron-Nitride material layer (hBN material layer). For example, the two-dimensional material layer may include at least one of BiOSe, Crl, WSe₂, CuSe₂, MoS₂, TaS, WS, CuS₂, SnSe, ReS, β-SnTe, MnO, AsS, P (black), InSe, h-BN, GaSe, GaN, SrTiO, MXene, and Janus 2D materials that may form a two-dimensional material.

The active patterns 42 may be disposed in the openings 28 of the interlayer insulating layer 24, respectively. For example, one active pattern 42 may be disposed in one opening 28, e.g., in a one-to-one correspondence.

In the cross-sectional structure illustrated in FIG. 2A, within one opening 28, the active pattern 42 may include a first active portion 46C1 disposed adjacent to the first gate electrode 31_1, a second active portion 46C2 disposed adjacent to the second gate electrode 31_2, and a lower active portion 46P extending from the first and second active portions 46C1 and 46C2. For example, as illustrated in FIG. 2A, the first active portion 46C1 may be conformal on the upper surface and lateral surface of the first gate electrode 31_1 (e.g., the lateral surface of the first gate electrode 31_1 that faces the second gate electrode 31_2), and the second active portion 46C2 may be conformal on the upper surface and lateral surface of the second gate electrode 31_2 (e.g., the lateral surface of the second gate electrode 31_2 that faces the first gate electrode 31_1).

In detail, the first active portion 46C1 may include a first vertical active portion 46V1 extending in the vertical direction (Z-direction), and a first upper bend portion 46E1a bent in the first direction from an upper region of the first vertical active portion 46V1 and oriented away from the opening 28. The second active portion 46C2 may include a second vertical active portion 46V2 extending in the vertical direction (Z-direction), and a second upper bend portion 46E2a bent in the first direction from an upper region of the second vertical active portion 46V2 and oriented away from the opening 28. The second direction may be a direction different from the first direction. The first upper bend portion 46E1a and the second upper bend portion 46E2a may be bent in opposite directions to extend away from each other along the X direction. In the active pattern 42, the first active portion 46C1 may further include a first lower bend portion 46E1b bent from a lower region of the first vertical active portion 46V1 in a direction approaching the second active portion 46C2, and the second active portion 46C2 may further include a second lower bend portion 46E2b bent from a lower region of the second vertical active portion 46V2 in a direction approaching the first active portion 46C1.

In the active pattern 42, the first lower bend portion 46E1b and the second lower bend portion 46E2b may be connected to each other (e.g., to define a single and uniform horizontal layer), and the lower active portion 46P may extend downward from the first and second lower bend portions 46E1b and 46E2b. The first active portion 46C1, the second active portion 46C2, and the lower active portion 46P may be integral with each other, e.g., seamlessly connected to each other into a same and uniform body. The lower active portion 46P may penetrate through the at least one buffer insulating layer 21 and may be in contact with the conductive line 12. The lower active portion 46P may be electrically connected to the conductive line 12. Accordingly, the active patterns 42 may be electrically connected to the conductive lines 12, i.e., the bit lines BL, while contacting (e.g., directly contacting) the conductive lines 12.

A direction in which the first upper bend portion 46E1a is bent from the upper region of the first vertical active portion 46V1 may be different from a direction in which the first lower bend portion 46E1b is bent from the lower region of the first vertical active portion 46V1. A direction in which the second upper bend portion 46E2a is bent from the upper region of the second vertical active portion 46V2 may be different from a direction in which the second lower bend portion 46E2b is bent from the lower region of the second vertical active portion 46V2.

The etch stop layer 37 may include an insulating material. For example, the etch stop layer 37 may be formed of an insulating material different from the interlayer insulating layer 24, e.g., the etch stop layer 37 may include silicon nitride, SiBN, SiCN, or insulating metal oxide. At least a portion of the etch stop layer 37 may be disposed between upper surfaces of the gate electrodes 31 and the first and second upper bend portions 46E1a and 46E2a of the active patterns 42. The etch stop layer 37 may be disposed on the upper surfaces of the gate electrodes 31 and an upper surface of the interlayer insulating layer 24. The etch stop layer 37 may be in contact (e.g., direct contact) with the upper surfaces of the gate electrodes 31 and the upper surface of the interlayer insulating layer 24.

The etch stop layer 37 may include a first etch stop layer 37_1 disposed between an upper surface of the first gate electrode 31_1 and the first upper bend portion 46E1a of the active pattern 42, and a second etch stop layer 37_2 disposed between an upper surface of the second gate electrode 31_2 and the second upper bend portion 46E2a of the active pattern 42.

Each of the dielectric layers 40 may include at least one of silicon oxide and a high-κ dielectric. The high-κ dielectric may be a dielectric having a higher dielectric constant than that of silicon oxide. The high-κ dielectric may include, e.g., a metal oxide or a metal oxynitride. For example, the high-κ dielectric may be formed of HfO₂, HfSiO, HfSiON, HfTaO, HfTiO, HfZrO, ZrO₂, Al₂O₃, or combinations thereof. Each of the dielectric layers 40 may be formed as a single layer or multiple layers of the materials described above. The dielectric layers 40 may extend, e.g., continuously, between the gate electrodes 31 and the active patterns 42, and between the etch stop layer 37 and the active patterns 42. For example, the dielectric layers 40 may include a first dielectric layer 40_1 and a second dielectric layer 40_2. At least a portion of the first dielectric layer 40_1 may be disposed between the first gate electrode 31_1 and the active pattern 42, and at least a portion of the second dielectric layer 40_2 may be disposed between the second gate electrode 31_2 and the active pattern 42. For example, the first dielectric layer 40_1 may be disposed between the first gate electrode 31_1 and the active pattern 42 and may be disposed between the first etch stop layer 37_1 and the active pattern 42, and the second dielectric layer 40_2 may be disposed between the second gate electrode 31_2 and the active pattern 42, and may be disposed between the second etch stop layer 37_2 and the active pattern 42.

The active patterns 42, the gate electrodes 31, and the dielectric layers 40 may constitute transistors TR_Ca. Each of the active patterns 42 may be referred to as and described as a channel region CH, a vertical channel region, a channel layer, or a channel pattern. The dielectric layers 40 may be gate dielectric layers. Hereinafter, components referred to with reference characters “CH” may be understood as channel regions even if there is no separate description thereof.

The intermediate structure 56 may further include an upper insulating layer 49 on the active patterns 42. The upper insulating layer 49 may fill the openings 28 on the active patterns 42.

The intermediate structure 56 may further include contact plugs 52 in contact with the etch stop layer 37 and the active patterns 42. For example, the contact plugs 52 may include a first contact plug 52_1 which penetrates through the upper insulating layer 49, the first upper bend portion 46E1a, and the first dielectric layer 40_1 to contact (e.g., directly contact) the first etch stop layer 37_1, and a second contact plug 52_2 which penetrates through the upper insulating layer 49, the second upper bend portion 46E2a, and the second dielectric layer 40_2 to contact (e.g., directly contact) the second etch stop layer 37_2.

The first upper bend portion 46E1a may surround, e.g., an entire perimeter of, a side surface of the first contact plug 52_1 and may be in contact (e.g., direct contact) with the first contact plug 52_1. The second upper bend portion 46E2a may surround, e.g., an entire perimeter of, a side surface of the second contact plug 52_2 and may be in contact (e.g., direct contact) with the second contact plug 52_2.

The third structure 70 may include an upper etch stop layer 58 and a data storage structure 61. The upper etch stop layer 58 may be disposed on the second structure 56. The upper etch stop layer 58 may include a material different from the upper insulating layer 49, e.g., the upper etch stop layer 58 may include silicon nitride.

The data storage structure 61 may include first electrodes 64 penetrating through the upper etch stop layer 58 and electrically connected to the contact plugs 52, a dielectric layer 66 covering the first electrodes 64 and the upper etch stop layer 58, and the second electrode 68 covering the dielectric layer 66.

In the top view as illustrated in FIG. 1, the contact plugs 52 may be arranged, e.g., spaced apart from each other, in the first direction (X-direction) and the second direction (Y-direction), and the first electrodes 64 may be arranged in the first direction (X-direction) and the second direction (Y-direction).

In one example, the data storage structure 61 may be a capacitor for storing information in a DRAM. For example, the dielectric layer 66 of the data storage structure 61 may be a capacitor dielectric layer of the DRAM, and the dielectric layer 66 may include, e.g., a high-κ dielectric material, silicon oxide, silicon nitride, silicon oxynitride, or combinations thereof.

In another example, the data storage structure 61 may be a structure that stores information of a memory different from that of the DRAM. For example, the data storage structure 61 may be a capacitor of a ferroelectric memory (FeRAM) disposed between the first and second electrodes 64 and 68 and including a dielectric layer 66 having a ferroelectric layer. For example, the dielectric layer 66 may be a ferroelectric layer configured to record data using a polarization state. In another example, the dielectric layer 66 may have a structure in which lower dielectric layers and ferroelectric layers are alternately stacked. Here, the lower dielectric layer may include at least one of, e.g., silicon oxide, silicon oxynitride, silicon nitride, and a high-κ dielectric. The high-κ dielectric may include, e.g., a metal oxide or a metal oxynitride. For example, the high-κ dielectric may be formed of HfO₂, HfSiO, HfSiON, HfTaO, HfTiO, HfZrO, ZrO₂, Al₂O₃, or combinations thereof.

When the data storage structure 61 is a capacitor that stores information in a ferroelectric memory (FeRAM), a ferroelectric layer of the dielectric layer 66 may include, e.g., an Hf-based compound, a Zr-based compound, and/or an Hf—Zr-based compound. For example, the Hf-based compound may be an HfO-based ferroelectric material, the Zr-based compound may include a ZrO-based ferroelectric material, and the Hf—Zr-based compound may include a hafnium zirconium oxide (HZO)-based ferroelectric material. The ferroelectric layer of the dielectric layer 66 of the data storage structure 61 may include a ferroelectric material doped with impurities, e.g., at least one of C, Si, Mg, Al, Y, N, Ge, Sn, Gd, La, Sc, and Sr. For example, the ferroelectric layer of the dielectric layer 66 of the data storage structure 61 may be a material in which at least one of HfO₂, ZrO₂, and HZO is doped with impurities, i.e., at least one of C, Si, Mg, Al, Y, N, Ge, Sn, Gd, La, Sc, and Sr.

As described above, the semiconductor device 1 may include the active pattern 42 including the first vertical active portion 46V1 extending in the vertical direction (Z-direction) and the first upper bend portion 46E1a bent from the upper region of the first vertical active portion 46V1, the first gate electrode 31_1 spaced apart from the active pattern 42, at least a portion of first gate electrode 31_1 facing the first vertical active portion 46V1, the first etch stop layer 37_1 in which at least a portion thereof is disposed between the upper surface of the first gate electrode 31_1 and the first upper bend portion 46E1a, the first dielectric layer 40_1 in which at least a portion thereof is disposed between the active pattern 42 and the first gate electrode 31_1, and the first contact plug 52_1 disposed on the first etch stop layer 37_1 and at least penetrating through the first upper bend portion 46E1a.

In an example embodiment, at least a portion of the active pattern 42 may be disposed on the same level as the gate electrodes 31 which may be the word line WL.

In an example embodiment, upper surfaces of the contact plugs 52 may be disposed on a level higher than an upper surface of the etch stop layer 37, e.g., relative to a bottom of the base 6. An upper end of the active pattern 42 may be disposed on a level higher than the lower surface of the etch stop layer 37 and may be disposed on a level higher than the gate electrodes 31, e.g., lower surfaces of the first and second upper bend portions 46E1a and 46E2a may be disposed at a level higher than the lower surface of the etch stop layer 37 and the upper surface of the gate electrodes 31 relative to a bottom of the base 6. A lower surface of the active pattern 42 may be disposed on a lower level than the gate electrodes 31, e.g., a lower surface of the lower active portion 46P may be at a lower level than a lower surface of the gate electrodes 31 relative to a bottom of the base 6.

According to example embodiments, the etch stop layer 37 may separate the contact plug 52 from the gate electrodes 31 by a desired distance. For example, by adjusting the thickness of the etch stop layers 37, the contact plug 52 and the gate electrodes 31 may be separated from each other by the desired distance. Accordingly, scattering characteristics of the semiconductor device 1 may be improved.

According to example embodiments, the etch stop layer 37 may serve to prevent an electrical short between the contact plug 52 and the gate electrodes 31. That is, since the active pattern 42 includes a portion extending to cover an upper surface of the etch stop layer 37, the contact plug 52 may be connected to the portion of the active pattern 42 covering the upper surface of the etch stop layer 37, while being separated from the gate electrodes 31 by the etch stop layer 37. Therefore, the etch stop layer 37 may prevent or substantially minimize an electrical short between the contact plug 52 and the gate electrodes 31 and the reliability of the semiconductor device 1 may be improved.

Hereinafter, various modified examples of the components of the above-described example embodiment will be described. Various modified examples of the components of the above-described embodiment will be described based on modified components or substituted components. Here, the components described above may be directly quoted without separate detailed explanation, or a description thereof may be omitted. Furthermore, modified or substitutable components described below will be described with reference to the drawings below, but components that may be deformed or substituted may be combined with each other or combined with the components described above to form a semiconductor device according to an example embodiment of the present disclosure.

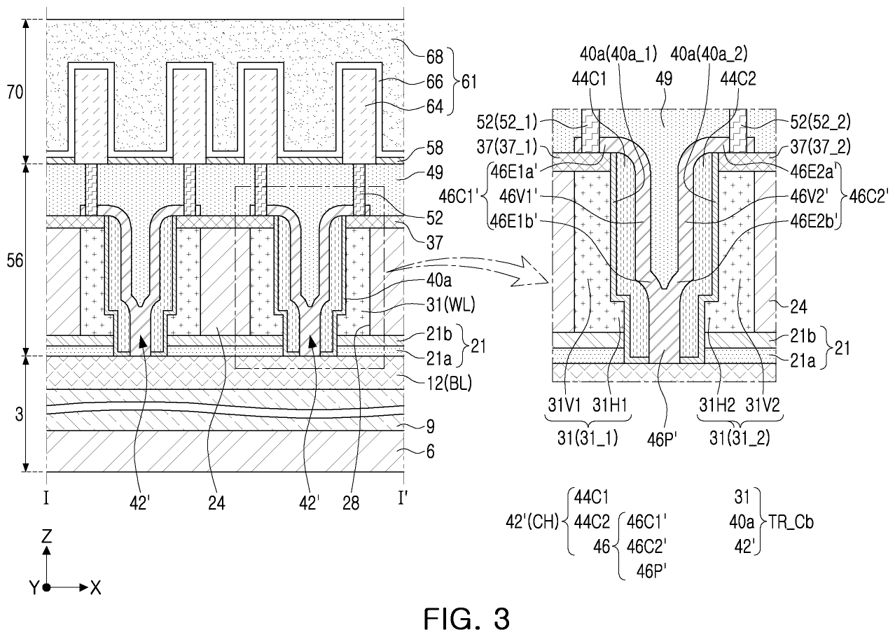

FIG. 3, which illustrates a cross-sectional structure taken along line I-I′ of FIG. 1, is a cross-sectional view illustrating a modified example of the active pattern 42 (see FIG. 2A) illustrated in FIG. 2A.

Referring to FIG. 3, the active pattern 42 illustrated in FIG. 2A may be deformed into an active pattern 42′ including at least two active layers. For example, the active pattern 42′ may include a first active layer 46, a second active layer 44C1, and a third active layer 44C2.

The first active layer 46 may include a first active portion 46C1′ disposed adjacent to the first gate electrode 31_1, a second active portion 46C2′ disposed adjacent to the second gate electrode 31_2, and a lower active portion 46P′ extending from the first and second active portions 46C1′ and 46C2′. The first active portion 46C1′ may include a first vertical active portion 46V1′ extending in the vertical direction (Z-direction), and a first upper bend portion 46E1a′ bent from an upper region of the first vertical active portion 46V1′ in a direction moving away from the second active portion 46C2′. The second active portion 46C2′ may include a second vertical active portion 46V2′ extending in the vertical direction (Z-direction), and a second upper bend portion 46E2a′ bent from an upper region of the second vertical active portion 46V2′ in a direction moving away from the first active portion 46C1′. In the first active layer 46, the first active portion 46C1′ may further include a first lower bend portion 46E1b′ bent from the lower region of the first vertical active portion 46V1′ in a direction approaching the second active portion 46C2′, and the second active portion 46C2′ may further include a second lower bend portion 46E2b′ bent from a lower region of the second vertical active portion 46V2′ in a direction approaching the first active portion 46C1′. In the first active layer 46, the first lower bend portion 46E1b′ and the second lower bend portion 46E2b′ may be connected to each other, and the lower active portion 46P′ may extend downward from the first and second lower bend portions 46E1b′ and 46E2b′. The lower active portion 46P′ may penetrate through the at least one buffer insulating layer 21 and may be in contact with the conductive line 12. The lower active portion 46P′ may be electrically connected to the conductive line 12.

The first upper bend portion 46E1a′ may cover an upper surface of the first etch stop layer 37_1. The first upper bend portion 46E1a′ may be in contact with the upper surface of the first etch stop layer 37_1. The second upper bend portion 46E2a′ may cover an upper surface of the second etch stop layer 37_2. The second upper bend portion 46E2a′ may be in contact with the upper surface of the second etch stop layer 37_2. The first contact plug 52_1 may penetrate through the first upper bend portion 46E1a′ and may be in contact with the first etch stop layer 37_1, and the second contact plug 52_2 may penetrate through the second upper bend portion 46E2a′ and may be in contact with the second etch stop layer 37_2.

The second active layer 44C1 may be disposed between the first active layer 46 and the first etch stop layer 37_1, between the first active layer 46 and the first gate electrode 31_1, and between the first active layer 46 and the at least one buffer insulating layer 21. The second active layer 44C1 may not vertically overlap the first etch stop layer 37_1. For example, the second active layer 44C1 may not cover the upper surface of the first etch stop layer 37_1. The second active layer 44C1 may be spaced apart from the first etch stop layer 37_1. The first dielectric layer 40a_1 may be disposed between the second active layer 44C1 and the first etch stop layer 37_1, between the second active layer 44C1 and the first gate electrode 31_1, between the second active layer 44C1 and the at least one buffer insulating layer 21, and between the second active layer 44C1 and the conductive line 12. The second active layer 44C1 may be spaced apart from the conductive line 12 by the first dielectric layer 40a_1.

The third active layer 44C2 may be disposed between the first active layer 46 and the second etch stop layer 37_2, between the first active layer 46 and the second gate electrode 31_2, and between the first active layer 46 and the at least one buffer insulating layer 21. The third active layer 44C2 may not vertically overlap the second etch stop layer 37_2. For example, the third active layer 44C2 may not cover the upper surface of the second etch stop layer 37_2. The third active layer 44C2 may be spaced apart from the second etch stop layer 37_2. The second dielectric layer 40a_2 may be disposed between the third active layer 44C2 and the second etch stop layer 37_2, between the third active layer 44C2 and the second gate electrode 31_2, between the third active layer 44C2 and the at least one buffer insulating layer 21, and between the third active layer 44C2 and the conductive line 12. The third active layer 44C2 may be spaced apart from the conductive line 12 by the second dielectric layer 40a_2.

The active patterns 42′, the gate electrodes 31, and the dielectric layers 40a may constitute transistors TR_Cb.

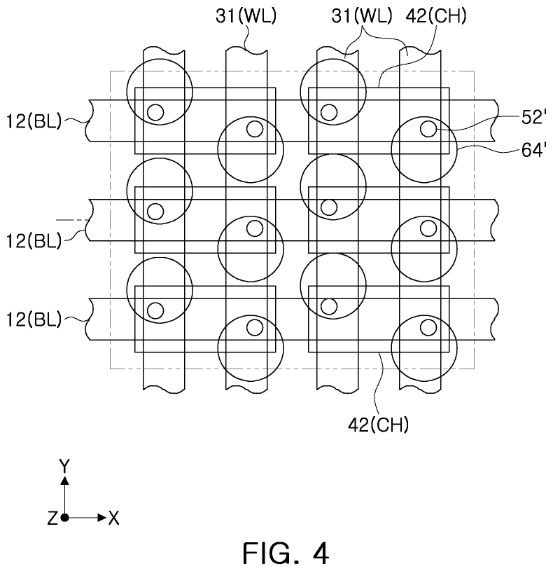

FIG. 4 is a top view schematically illustrating a modified example of a semiconductor device according to an example embodiment of the present disclosure.

Referring to FIG. 4, the first electrodes 64′ (see FIG. 1) arranged in the first direction (X-direction) and the second direction (Y-direction) illustrated in FIG. 1 may be arranged in a zigzag manner in the first direction (X-direction) or the second direction (Y-direction) to increase an arrangement density. The contact plugs 52′ may be arranged in a zigzag manner along the first direction (X-direction) or the second direction (Y-direction).

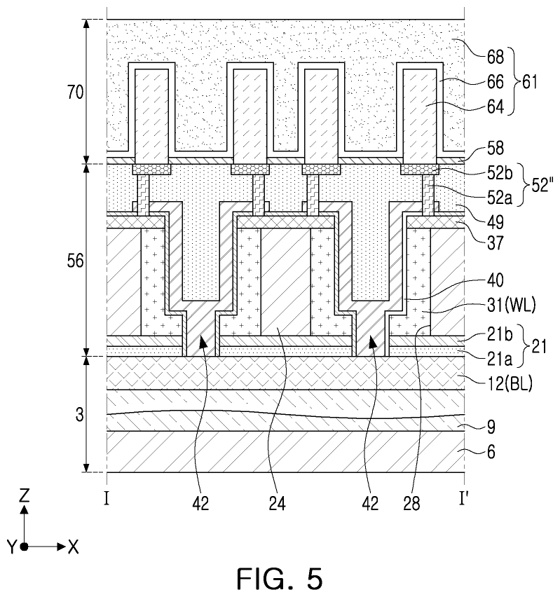

FIG. 5 is a schematic cross-sectional view illustrating a modified example of the contact plugs 52 (see FIG. 2A) illustrated in FIG. 2A.

Referring to FIG. 5, each of the contact plugs 52 may include a plug portion 52a and a pad portion 52b in contact with the first electrode 64 on the plug portion 52a. A width of the pad portion 52b may be greater than a width of the plug portion 52a (e.g., in the X direction).

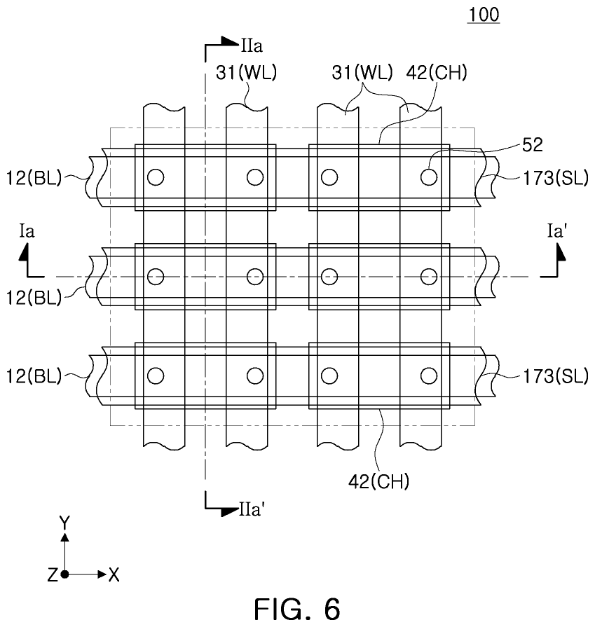

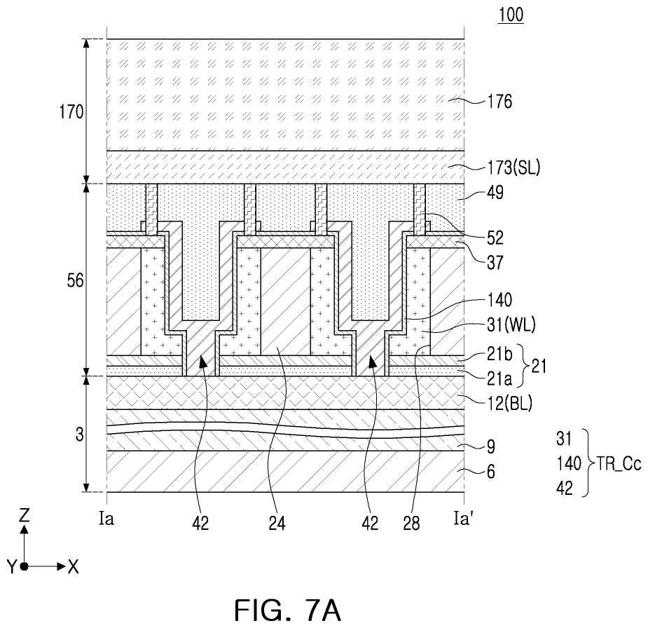

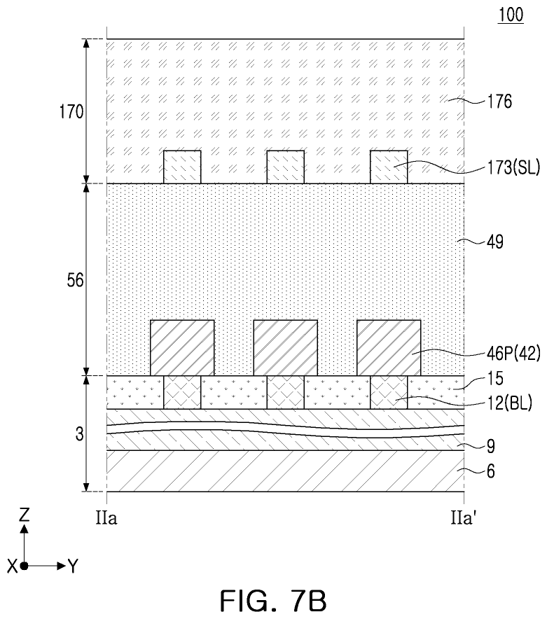

FIG. 6 is a top view schematically illustrating a modified example of a semiconductor device according to an example embodiment of the present disclosure, FIG. 7A is a cross-sectional view along line Ia-Ia′ of FIG. 6, and FIG. 7B is a cross-sectional view along line IIa-IIa′ of FIG. 6.

Referring to FIGS. 6, 7A, and 7B, the dielectric layers 40 in FIG. 2A may be substituted with dielectric layers (hereinafter, also referred to as data storage layers) 140 configured to store information, and the third structure 70 (see FIGS. 2A and 2B) may be substituted with a third structure 170 including upper conductive lines 173 and an upper capping insulating layer 176.

The dielectric layers 140 configured to store information may be information storage layers. For example, each of the dielectric layers 140 may include a ferroelectric layer configured to store information. The ferroelectric layer configured to store information may have polarization characteristics according to an electric field applied by the gate electrodes 31, i.e., the word lines WL, and may have remnant polarization by a dipole even in the absence of an external electric field. Data may be recorded using a polarization state in the ferroelectric layer of the dielectric layers 140 as described above.

The ferroelectric layer of the dielectric layers 140 may include, e.g., at least one of an Hf-based compound, a Zr-based compound, or an Hf—Zr-based compound. For example, the Hf-based compound may be an HfO-based ferroelectric material, the Zr-based compound may include a ZrO-based ferroelectric material, and the Hf—Zr-based compound may include a hafnium zirconium oxide (HZO)-based ferroelectric material. The ferroelectric layer of the dielectric layers 140 may include a ferroelectric material doped with impurities, e.g., at least one of C, Si, Mg, Al, Y, N, Ge, Sn, Gd, La, Sc and Sr. For example, the dielectric layers 140 may be materials in which at least one of HfO₂, ZrO₂, and HZO is doped with impurities, e.g., at least one of C, Si, Mg, Al, Y, N, Ge, Sn, Gd, La, Sc and Sr.

Each of the dielectric layers 140 may have a structure in which lower dielectric layers and ferroelectric layers are alternately stacked on each other. Here, the lower dielectric layer may include, e.g., at least one of silicon oxide, silicon oxynitride, silicon nitride, and high-κ dielectric. The high-κ dielectric may include a metal oxide or a metal oxynitride. For example, the high-κ dielectric may be formed of HfO₂, HfSiO, HfSiON, HfTaO, HfTiO, HfZrO, ZrO₂, Al₂O₃, or combinations thereof.

The dielectric layers 140, the active patterns 42, and the gate electrodes 31 may constitute memory cell transistors TR_Cc configured to store information.

Each of the upper conductive lines 173 may have a line shape extending in the first direction (X-direction). The upper conductive lines 173 may be electrically connected to the contact plugs 52. The upper conductive lines 173 may be referred to as a source line SL or a source pattern. The upper conductive lines 173 may vertically overlap the conductive lines 12.

Accordingly, there may be provided a semiconductor device 100 including the conductive lines 12 that may be the bit lines BL, the memory cell transistors TR_Cc that may store information, and the upper conductive lines 173 that may be the source lines SL.

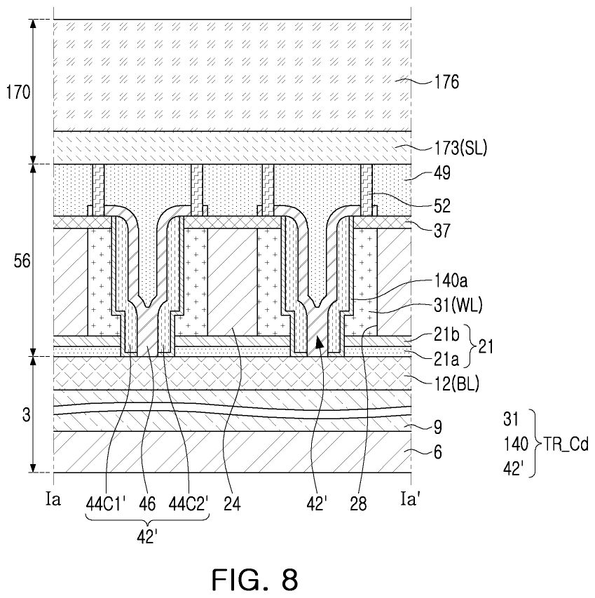

FIG. 8 is a cross-sectional structure taken along the line Ia-Ia′ of FIG. 6 and is a cross-sectional view illustrating a modified example of the active pattern 42 (see FIG. 7A) illustrated in FIG. 7A.

Referring to FIG. 8, the active pattern 42 (see FIG. 7A) described in FIG. 7A may be substituted with the active pattern 42′ illustrated in FIG. 3. For example, the active pattern 42′ may include the first active layer 46, the second active layer 44C1′, and the third active layer 44C2′, as described in FIG. 3. Since the detailed explanation of the active pattern 42′ is described in FIG. 3, the detailed description thereof will be omitted.

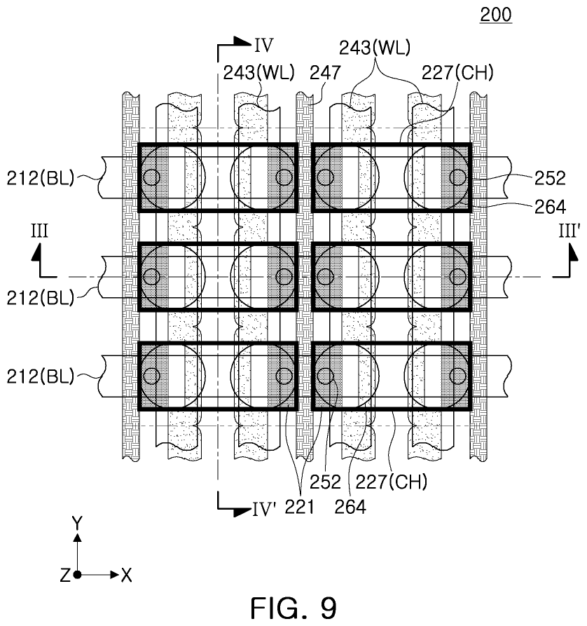

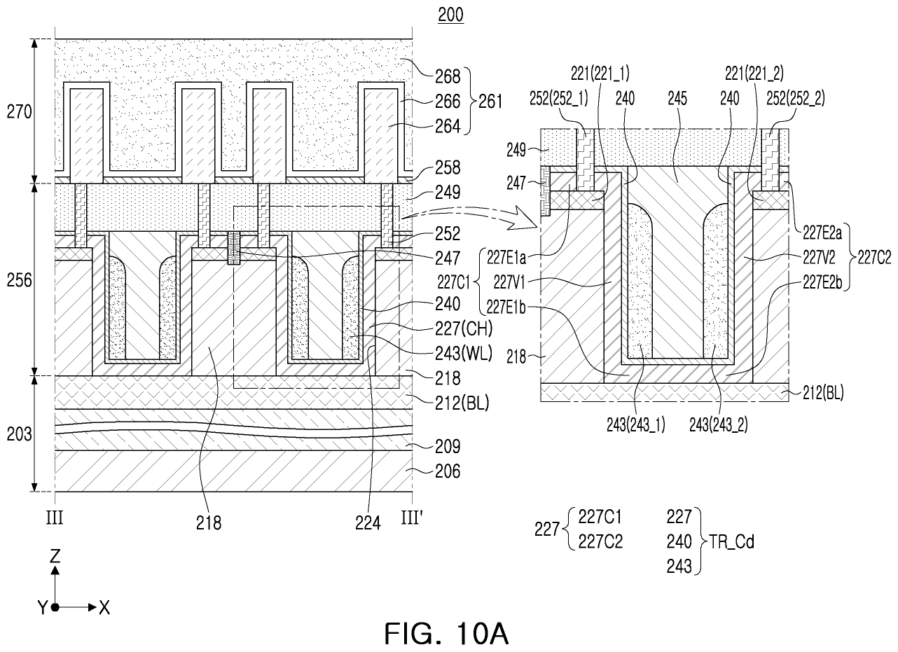

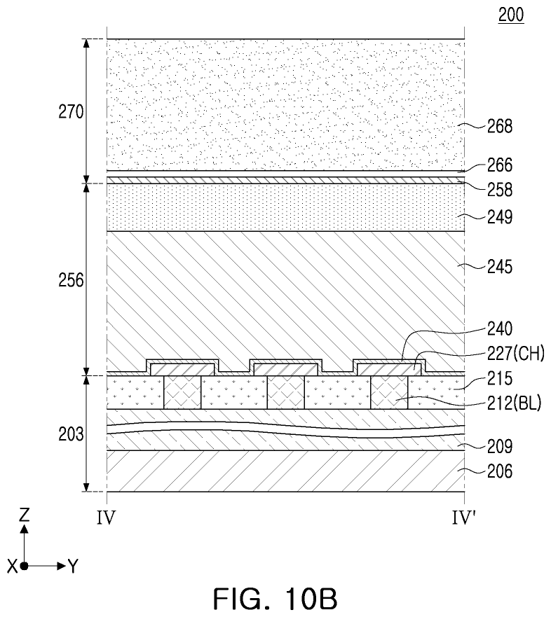

FIGS. 9, 10A, and 10B are views schematically illustrating a modified example of a semiconductor device according to an example embodiment of the present disclosure. FIG. 9 is a top view schematically illustrating a modified example of a semiconductor device according to an example embodiment of the present disclosure. FIG. 10A is a cross-sectional view along line III-III′ of FIG. 9, and FIG. 10B is a cross-sectional view along line IV-IV′ of FIG. 9.

Referring to FIGS. 9, 10A, and 10B, a semiconductor device 200 according to an example embodiment of the present disclosure may include a first structure 203, a second structure 256 on the first structure 203, and a third structure 270 on the second structure 256.

The first structure 203 may be substantially the same as the first structure 3 illustrated in FIGS. 2A and 2B. Accordingly, the first structure 203 may include a base 206, a lower insulating layer 209, conductive lines 212, and an intermetallic insulating layer 215, corresponding to the base 6, the lower insulating layer 9, the conductive lines 12, and the intermetallic insulating layer 15, respectively. The conductive lines 212 may be bit lines BL.

The second structure 256 may include an interlayer insulating layer 218, gate electrodes 243, dielectric layers 240, active patterns 227, etch stop layers 221, and insulating separation patterns 247.

The interlayer insulating layer 218 may have openings 224. The etch stop layers 221 may be disposed on the interlayer insulating layer 218. The etch stop layers 221 may have side surfaces vertically aligned with a side surface of the interlayer insulating layer 218. The etch stop layers 221 may be in contact with an upper surface of the interlayer insulating layer 218. The etch stop layer 221 may include a conductive material. For example, the etch stop layer 221 may include doped polysilicon, a metal, a conductive metal nitride, a metal-semiconductor compound, a conductive metal oxide, conductive graphene, carbon nanotubes, or combinations thereof. For example, the etch stop layer 221 may include at least one of TiN, TaN, WN, NbN, TiAl, TiAlN, TiSi, TiSiN, TaSi, TaSiN, RuTiN, NiSi and CoSi.

The active patterns 227 may e.g., conformally, cover internal walls of each of the openings 224 and may cover the upper surface of the etch stop layer 221 on the interlayer insulating layer 218.

When one of the openings 224 is viewed as a center, the etch stop layer 221 may include a first etch stop layer 221_1 in contact with the upper surface of the interlayer insulating layer 218 disposed on a first side of the opening 224, and a second etch stop layer 221_2 in contact with the upper surface of the interlayer insulating layer 218 disposed on a second side of the opening 224.

The active pattern 227 may include a first active portion 227C1 and a second active portion 227C2.

The first active portion 227C1 may include a first vertical active portion 227V1 covering a first side surface of the opening 224, a first upper bend portion 227E1a bent from an upper region of the first vertical active portion 227V1 and covering an upper surface of the first etch stop layer 221_1, and a first lower bend portion 227E1b bent from a lower region of the first vertical active portion 227V1 and in contact with the conductive line 212. The first vertical active portion 227V1 may be in contact with a side surface of the interlayer insulating layer 218 and a side surface of the first etch stop layer 221_1. The first upper bend portion 227E1a may be in contact with the upper surface of the first etch stop layer 221_1.

The second active portion 227C2 may include a second vertical active portion 227V2 covering the second side surface of the opening 224, a second upper bend portion 227E2a bent from an upper region of the second vertical active portion 227V2 and covering an upper surface of the second etch stop layer 221_2, and a second lower bend portion 227E2b bent from a lower region of the second vertical active portion 227V2 and in contact with the conductive line 212. The second vertical active portion 227V2 may be in contact with a side surface of the interlayer insulating layer 218 and a side surface of the second etch stop layer 221_2. The second upper bend portion 227E2a may be in contact with the upper surface of the second etch stop layer 221_2.

The first and second lower bend portions 227E1b and 227E2b may be connected to each other and be integrally formed. When one of the openings 224 is viewed as a center, the dielectric layer 240 may conformally cover upper surfaces of the first and second lower bend portions 227E1b and 227E2b, side surfaces of the first and second vertical active portions 227V1 and 227V2, and upper surfaces of the first and second upper bend portions 227E1a and 227E2a.

When one of the openings 224 is viewed as a center, the gate electrodes 243 may include a first gate electrode 243_1 and a second gate electrode 243_2 parallel to each other. The first gate electrode 243_1 may be disposed on the first lower bend portion 227E1b and may be disposed adjacent to the first vertical active portion 227V1. The second gate electrode 243_2 may be disposed on the second lower bend portion 227E2b and may be disposed adjacent to the second vertical active portion 227V2. The first and second gate electrodes 243_1 and 243_2 may be spaced apart from the active pattern 227 by the dielectric layer 240. For example, as illustrated in FIG. 10A, each of the first gate electrode 243_1 and the second gate electrode 243_2 is separated from the first contact plug 252_1 and the second contact plug 252_2, respectively, by the dielectric layer 240.

The active patterns 227 may be substantially the same material as the active patterns 42 described in FIGS. 1, 2A, and 2B. The dielectric layers 240 may be substantially the same material as the dielectric layers 40 illustrated in FIG. 2A. The gate electrodes 243 may be substantially the same material as the gate electrodes 31 illustrated in FIGS. 1, 2A, and 2B.

In one example, as illustrated in FIG. 10A, an upper end of each of the gate electrodes 243 may be disposed on a level higher than a lower surface of the etch stop layer 221, e.g., relative to a bottom of the base 206. The gate electrodes 243 may be disposed on the same level as a portion of each of the active patterns 227, e.g., lateral surfaces of the gate electrodes 243 and the active patterns 227 may overlap in the X direction. In another example, the upper end of each of the gate electrodes 243 may be disposed on the same level as the lower surface of the etch stop layer 221.

The active patterns 227, the gate electrodes 243, and the dielectric layers 240 may constitute transistors TR_Cd. Each of the active patterns 227 may be referred to as and described as a channel region, a channel layer, or a channel pattern. The gate electrodes 243 may be word lines WL.

The insulating separation pattern 247 may penetrate through the etch stop layer 221, the active pattern 227, and the dielectric layer 240 on the interlayer insulating layer 218. On the interlayer insulating layer 218, the active pattern 227 may be separated by the insulating separation pattern 247, and the etch stop layer 221 may be separated by the insulating separation pattern 247. The insulating separation pattern 247 may include an insulating material, e.g., silicon oxide or silicon nitride.

The second structure 256 may further include a gap fill insulating layer 245 covering the dielectric layer 240 and the gate electrodes 243 inside the opening 224. The second structure 256 may further include an upper insulating layer 249 disposed on the gap fill insulating layer 245, the dielectric layer 240, and the insulating separation pattern 247.

The second structure 256 may further include contact plugs 252 penetrating through the upper insulating layer 249, the dielectric layer 240, and the upper bend portions 227E1a and 227E2a of the active patterns 227 to contact the etch stop layers 221. The contact plugs 252 may be electrically connected to the etch stop layers 221. The contact plugs 252 may include a first contact plug 252_1 penetrating through the upper insulation layer 249, the dielectric layer 240, and the first upper bend portion 227E1a of the active pattern 227 to contact the first etch stop layer 221_1, and a second contact plug 252_2 penetrating through the upper insulating layer 249, the dielectric layer 240 and the second upper bend portion 227E2a of the active pattern 227 to contact the second etch stop layer 221_2. The first contact plug 252_1 may be electrically connected to the first etch stop layer 221_1, and the second contact plug 252_2 may be electrically connected to the second etch stop layer 221_2.

The third structure 270 may be substantially the same as the third structure 70 illustrated in FIGS. 1, 2A, and 2B. For example, the third structure 270 may include an upper etch stop layer 258 and a data storage structure 261 corresponding to the upper etch stop layer 58 and the data storage structure 61 described in FIGS. 1, 2A, and 2B, respectively.

The upper etch stop layer 258 may be disposed on the second structure 256, and the data storage structure 261 may include first electrodes 264 penetrating through the upper etch stop layer 258 and electrically connected to the contact plugs 252, a dielectric layer 266 covering the first electrodes 264 and the upper etch stop layer 258, and a second electrode 268 covering the dielectric layer 266.

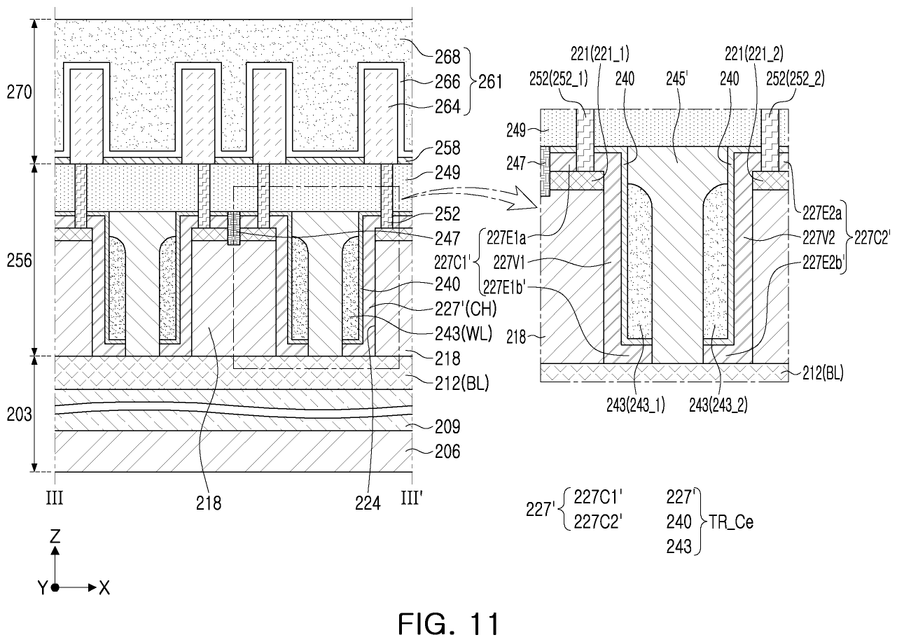

FIG. 11 is a cross-sectional structure taken along line III-III′ of FIG. 9 and is a cross-sectional view illustrating a modified example of the active pattern 227 (see FIG. 10A) and the gap fill insulating layer 245 (see FIG. 10A) illustrated in FIG. 10A.

Referring to FIG. 11, the first and second lower bend portions 227E1b and 227E2b (FIG. 10A) which are connected to each other and integrally formed may be deformed into a first lower bend portion 227E1b′ and a second lower bend portion 227E2b′ spaced apart from each other (e.g., in the X direction). The gap fill insulating layer 245 (see FIG. 10A) illustrated in FIG. 10A may be deformed into a gap fill insulating layer 245′ penetrating through the dielectric layer 240 and extending between the first lower bend portion 227E1b′ and the second lower bend portion 227E2b′ to contact (e.g., directly contact) the conductive lines 212. Accordingly, the first active portion 227C1 and the second active portion 227C2 described in FIG. 10A may be deformed into a first active portion 227C1′ and a second active portion 227C2′ separated from each other by the gap fill insulating layer 245′, and the active pattern 227 described in FIG. 10A may be deformed into an active pattern 227′ including the first active portion 227C1′ and the second active portion 227C2′ spaced apart from each other. The dielectric layer 240, the active pattern 227′, and the gate electrode 243 may constitute a transistor TR_Ce.

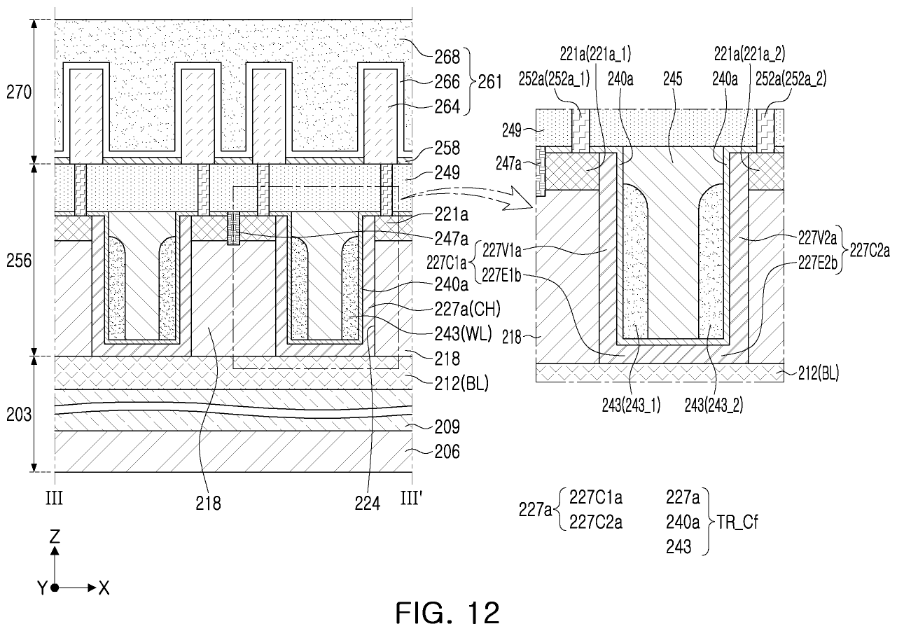

FIG. 12 is a cross-sectional structure taken along line III-III′ of FIG. 9 and is a cross-sectional view illustrating a modified example of the active pattern 227 (see FIG. 10A) illustrated in FIG. 10A.

Referring to FIG. 12, the active pattern 227 (see FIG. 10A) described in FIG. 10A may be substituted with an active pattern 227a in which the first and second upper bend portions 227E1a and 227E2a are omitted. For example, the active pattern 227a may include a first active portion 227C1a and a second active portion 227C2a, the first active portion 227C1a may include a first vertical active portion 227V1a and a first lower bend portion 227E1b bent from a lower region of the first vertical active portion 227V1a and in contact with the conductive line 212, and the second active portion 227C2a may include a second vertical active portion 227V2a and a second lower bend portion 227E2b bent from a lower region of the second vertical active portion 227V2a and in contact with the conductive line 212.

In one example, the first and second lower bend portions 227E1b and 227E2b may be connected to each other, as illustrated in FIG. 10A, and may be integrally formed. In a modified example, the first and second lower bend portions 227E1b and 227E2b may be deformed to be spaced apart from each other, as illustrated in FIG. 11.

As illustrated in FIG. 12, the etch stop layer 221 (see FIG. 10A) and the dielectric layer 240 (see FIG. 10A) spaced apart from each other may be deformed into an etch stop layer 221a and a dielectric layer 240a in contact with each other. For example, the etch stop layer 221a may include a first etch stop layer 221a_1 and a second etch stop layer 221a_2. A side surface of the first etch stop layer 221a_1 may be in contact with the first vertical active portion 227V1a, and an upper surface of the first etch stop layer 221a_1 may be in contact with the dielectric layer 240a. A side surface of the second etch stop layer 221a_2 may be in contact with the second vertical active portion 227V2a, and the upper surface of the second etch stop layer 221a_2 may be in contact with the dielectric layer 240a.

The dielectric layer 240a, the active pattern 227a, and the gate electrode 243 may constitute a transistor TR_Cf.

The insulating separation pattern 247 in FIG. 10A may be deformed into an insulating separation pattern 247a penetrating through the etch stop layer 221a and the dielectric layer 240a on the interlayer insulating layer 218 to contact the etch stop layer 221a, and spaced apart from the active pattern 227a.

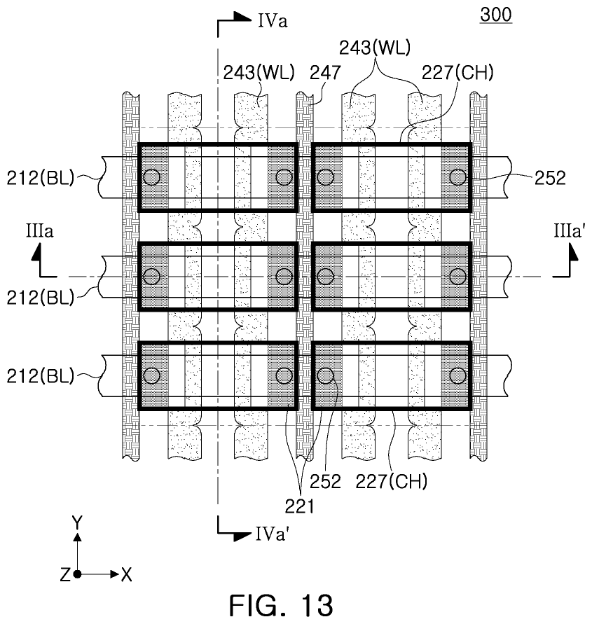

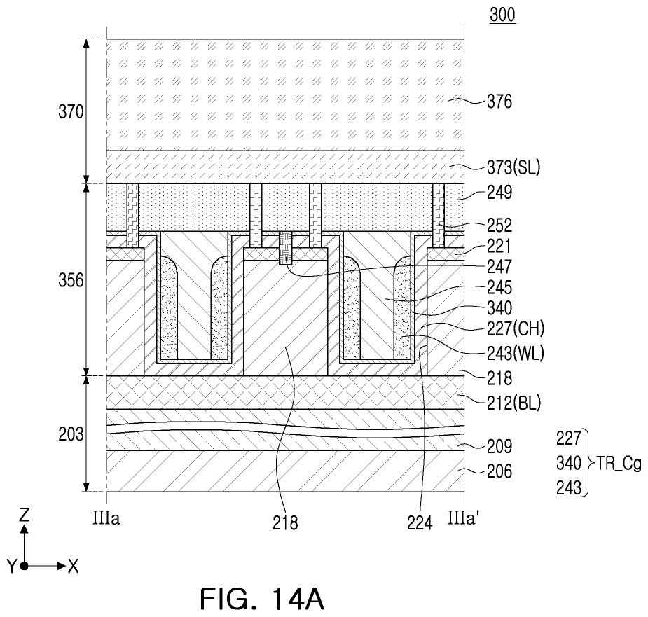

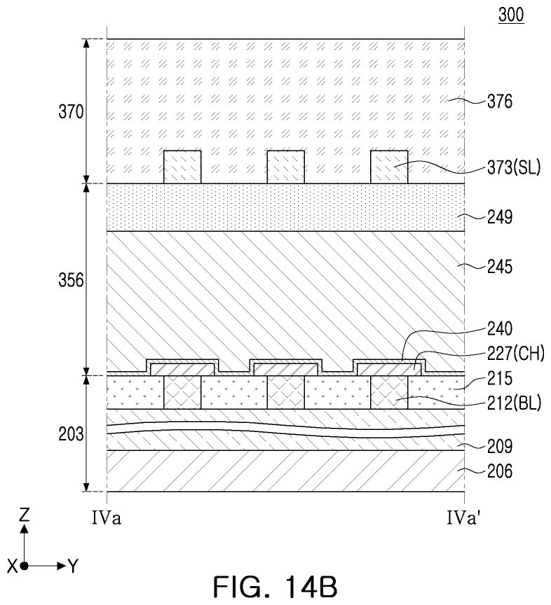

FIG. 13 is a top view schematically illustrating a modified example of a semiconductor device according to an example embodiment of the present disclosure. FIG. 14A is a cross-sectional view along line IIIa-IIIa′ of FIG. 13, and FIG. 14B is a cross-sectional view along line IVa-IVa′ of FIG. 13.

Referring to FIGS. 13, 14A, and 14B, in the semiconductor device 200 illustrated in FIGS. 9, 10A, and 10B, the dielectric layers 240 (see FIGS. 10A and 10B) may be substituted with dielectric layers 340 configured to store information, and the third structure 270 (see FIGS. 10A and 10B) may be substituted with a third structure 370 including upper conductive lines 373 and an upper capping insulating layer 376. The second structure 256 (see FIGS. 10A and 10B) illustrated in FIGS. 9, 10A and 10B may be deformed into a second structure 356 including the dielectric layers 340 configured to store information.

The dielectric layers 340 may be substantially the same material as the dielectric layers 140 illustrated in FIG. 7A. The dielectric layers 340, the active patterns 227, and the gate electrodes 243 may constitute memory cell transistors TR_Cg configured to store information.

The third structure 370 may have substantially the same structure as the third structure 170 (see FIGS. 7A and 7B) illustrated in FIGS. 6, 7A and 7B. For example, the upper conductive lines 373 may be electrically connected to the contact plugs 252, and the upper capping insulating layer 376 may cover the upper conductive lines 373.

Each of the upper conductive lines 373 may have a line shape extending in the first direction (X-direction). The upper conductive lines 373 may be referred to as a source line SL or a source pattern. The upper conductive lines 373 may vertically overlap the conductive lines 212.

Accordingly, there may be provided a semiconductor device 300 including the conductive lines 212 that may be the bit lines BL, the memory cell transistors TR_Cg that may store information, and the upper conductive lines 373 that may be the source lines SL.

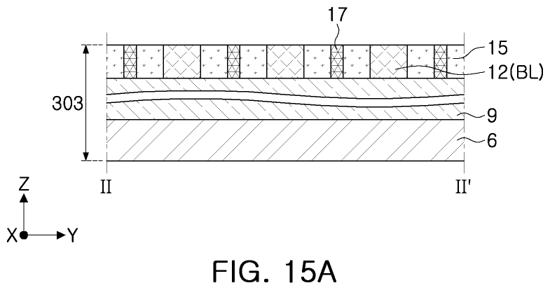

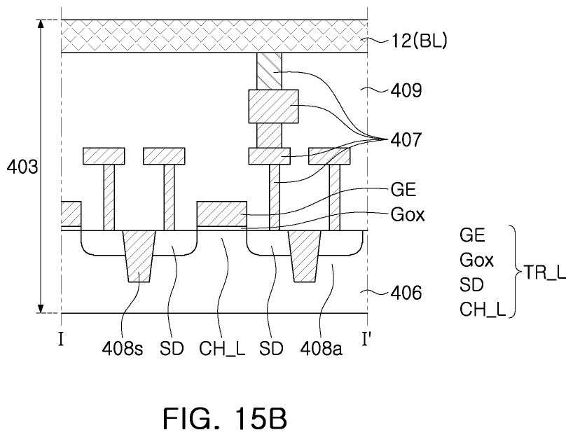

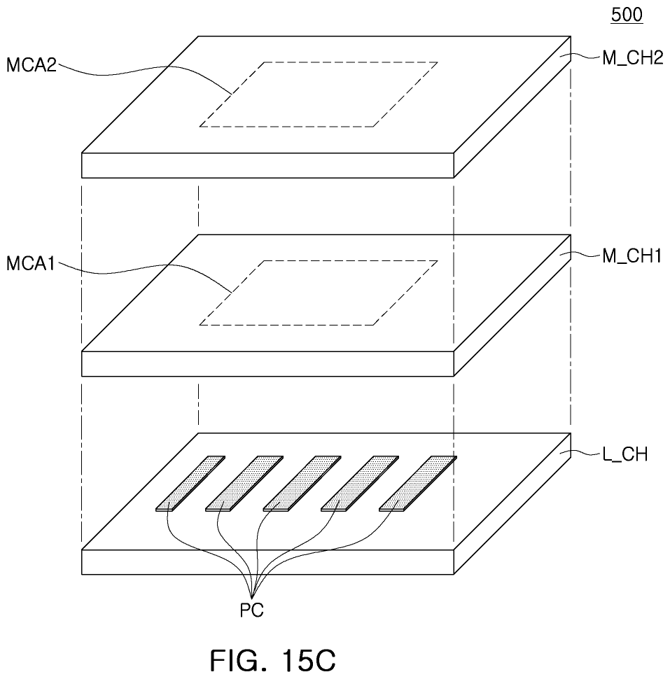

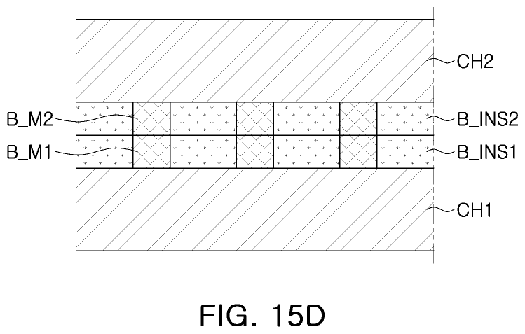

FIG. 15A is a cross-sectional view illustrating the first structure described in the previous example embodiments, e.g., a first structure with which the first structure 3 (see FIGS. 2B and 7B) in FIGS. 2B and 7B and the first structure 203 (see FIGS. 10B and 14B) in FIGS. 10B and 14B may be substituted.

Referring to FIG. 15A, the first structure 3 (see FIGS. 2B and 7B) in FIGS. 2B and 7B, and the first structure 203 (see FIGS. 10B and 14B) in FIGS. 10B and 14B may be substituted with a first structure 303 further including shield patterns 17.

The shield patterns 17 may be disposed between the conductive lines 12, as illustrated in FIG. 2B. For example, each of the shield patterns 17 may be disposed between a pair of conductive lines 12 disposed adjacent to each other.

The shield patterns 17 may be formed of a conductive material. For example, the shield patterns 17 may include doped polysilicon, a metal, a conductive metal nitride, a metal-semiconductor compound, a conductive metal oxide, graphene, carbon nanotubes, or combinations thereof. The shield patterns 17 may serve to screen the conductive lines 12 disposed adjacent to each other, i.e., capacitive coupling between the bit lines BL. For example, the shield patterns 17 may minimize an RC delay in the bit lines BL by reducing or blocking parasitic capacitance between the bit lines BL disposed adjacent to each other.

For example, the first structure 303 in FIG. 15A may include the shield patterns 17 between the conductive lines 12 of the first structure 3, as illustrated in FIG. 2B. In another example, the shield patterns 17 may be disposed between the conductive lines 212 illustrated in FIG. 10B.

FIG. 15B is a cross-sectional view illustrating the first structure described in the previous example embodiments, e.g., a first structure with which the first structure 3 in FIGS. 2A and 2B, and 7A and 7B, the first structure 203 in FIGS. 10A and 10B, and 14A and 14B, and the first structure 303 in FIG. 15A may be substituted.

Referring to FIG. 15B, the first structure with which the first structure 3 in FIGS. 2A and 2B, and 7A and 7B, the first structure 203 in FIGS. 10A and 10B, and 14A and 14B, and the first structure 303 in FIG. 15A may be substituted, may include a base 406, a circuit element TR_L on the base 406, a lower insulating structure 409 covering the circuit element TR_L on the base 406, and a wiring structure 407 electrically connected to the circuit element TR_L on the base 406 and embedded in the lower insulating structure 409.

The first structure 403 may further include the first structure 3 in FIGS. 2A and 2B, and 7A and 7B, the first structure 203 in FIGS. 10A and 10B, and 14A and 14B, and bit lines BL as in the first structure 303 of FIG. 15A. For example, the bit lines BL may be the conductive lines 12 of the first structure 3 in FIGS. 2A and 2B, and 7A and 7B. The conductive lines 12, i.e., the bit lines BL, may be disposed on the lower insulating structure 409 and the wiring structure 407, and may be electrically connected to the wiring structure 407. The wiring structure 407 may be electrically connected to the circuit element TR_L. The wiring structure 407 may have a multilayer structure including a plug portion and a wiring portion.

The base 406 may be a semiconductor substrate. The circuit element TR_L may include a peripheral transistor. For example, a peripheral transistor of the circuit element TR_L may include gate structure GE and Gox disposed on a peripheral active region 408a defined by a device isolation region 408s in the base 406, and peripheral source/drain regions SD disposed in the peripheral active region 408a on both sides of the gate structure GE and Gox. The peripheral active region 408a between the peripheral source/drain regions SD may be defined as a channel region CH_L. The gate structure GE and Gox may include a peripheral gate electrode GE and a peripheral gate dielectric layer Gox between the peripheral gate electrode GE and the peripheral active region 408a.

FIG. 15C is a conceptual perspective view illustrating an example of a semiconductor device according to an example embodiment of the present disclosure.

Referring to FIG. 15C, a semiconductor device 500 according to an example embodiment of the present disclosure may include a plurality of stacked chips L_CH, M_CH1, and M_CH2. For example, the plurality of stacked chips L_CH, M_CH1, and M_CH2 of the semiconductor device 500 may include a logic chip L_CH, a first memory chip M_CH1 that vertically overlaps the logic chip L_CH, and a second memory chip M_CH2 that vertically overlaps the first memory chip M_CH1. In the semiconductor device 500, one of the logic chip L_CH, the first memory chip M_CH1, and the second memory chip M_CH2 may be omitted.

The logic chip L_CH, the first memory chip M_CH1, and the second memory chip M_CH2 may be sequentially stacked. For example, the logic chip L_CH may be disposed between the first memory chip M_CH1 and the second memory chip M_CH2. In another example, the logic chip L_CH may be disposed on the second memory chip M_CH2.

The logic chip L_CH may include a peripheral circuit PC for operating at least one of the first memory chip M_CH1 and the second memory chip M_CH2. The first memory chip M_CH1 may include a first memory cell array MCA1 configured to store information, and the second memory chip M_CH2 may include a second memory cell array MCA2 configured to store information.

In one example, at least one of the first memory chip M_CH1 and the second memory chip M_CH2 may include a semiconductor device according to any one of the example embodiments described above. For example, at least one of the first memory chip M_CH1 and the second memory chip M_CH2 may include the semiconductor device 1 illustrated in FIGS. 1, 2A and 2B, the semiconductor device 100 illustrated in FIGS. 6, 7A and 7B, the semiconductor device 200 illustrated in FIGS. 9, 10A and 10B, or the semiconductor device 300 illustrated in FIGS. 13, 14A and 14B.

In another example, one of the first memory chip M_CH1 and the second memory chip M_CH2 may include a semiconductor device according to any one of the example embodiments, and the other thereof may include a nonvolatile memory device, e.g., a flash memory.

FIG. 15D is a conceptual cross-sectional view illustrating bonding between the stacked chips illustrated in FIG. 15C.

In addition to FIG. 15C, referring to FIG. 15D, lower bonding regions B_M1 and B_INS1 may be disposed on a lower chip CH1, and upper bonding regions B_M2 and B_INS2 may be disposed beneath an upper chip CH2. The lower bonding regions B_M1 and B_INS1 may be in contact with and be bonded to the upper bonding regions B_M2 and B_INS2.

The lower bonding regions B_M1 and B_INS1 may include a lower bonding pad B_M1 and a lower bonding insulating layer B_INS1 having an upper surface forming a coplanar surface. The upper bonding regions B_M2 and B_INS2 may include an upper bonding pad B_M2 and an upper bonding insulating layer B_INS2 having a lower surface forming a coplanar surface.

The lower bonding regions B_M1 and B_INS1 may be bonded to and be in contact with the upper bonding regions B_M2 and B_INS2 by intermetallic bonding. Here, in example embodiments, “intermetallic bonding” denotes bonding pads of the same metal to each other by a thermal pressure bonding process. For example, the lower bonding regions B_M1 and B_INS1 and the upper bonding regions B_M2 and B_INS2 may include metal materials, e.g., copper (Cu), and may be bonded to and be in contact with each other by Cu—Cu bonding.

In an example embodiment, among the plurality of stacked chips L_CH, M_CH1 and M_CH2 of the semiconductor device 500 described in FIG. 15C, the stacked chips that are adjacent and bonded to each other may further include the lower bonding regions B_M1 and B_INS1 and the upper bonding regions B_M2 and B_INS2. For example, a chip disposed at a lower portion of the plurality of stacked chips L_CH, M_CH1 and M_CH2, e.g., the first memory chip M_CH1, may include the lower bonding regions B_M1 and B_INS1, and a chip disposed at an upper portion thereof, e.g., the second memory chip M_CH2, may include the upper bonding regions B_M2 and B_INS2 that are bonded to and in contact with the lower bonding regions B_M1 and B_INS1.

Next, exemplary embodiments of a method of forming a semiconductor device according to the above-described embodiments will be described.

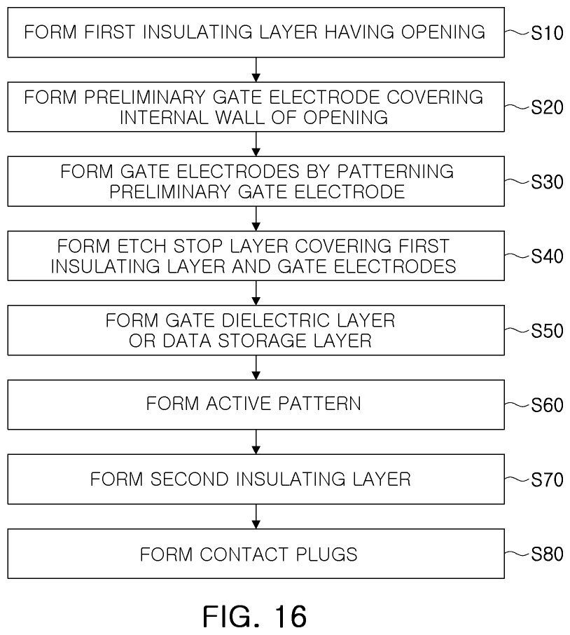

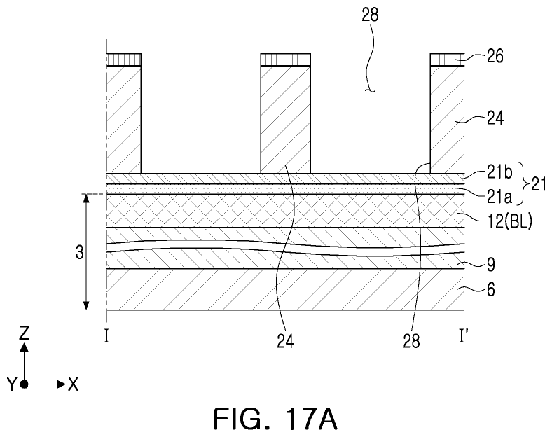

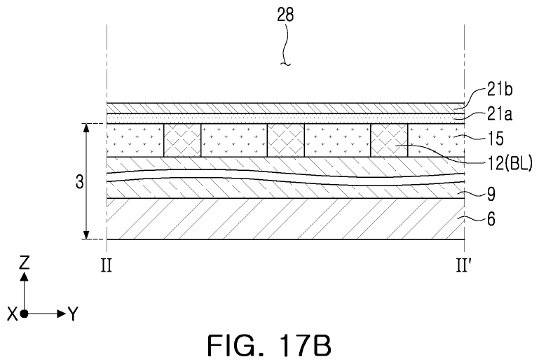

First, an exemplary embodiment of a method of forming a semiconductor device will be described with reference to FIGS. 16 and 17A to 21B. FIG. 16 is a schematic process flowchart illustrating an example of a method of forming a semiconductor device according to example embodiments. FIGS. 17A, 18A, 19A, 20A and 21A are cross-sectional views schematically illustrating a region taken along line I-I′ of FIG. 1, and FIGS. 17B, 18B, 19B, 20B, and 21B are cross-sectional views schematically illustrating a region taken along line II-II′ of FIG. 1.

Referring to FIGS. 16, 17A, and 17B, a first structure 3 may be formed. The first structure 3 may include the base 6, the lower insulating layer 9 disposed on the base 6, and the conductive lines 12 and the intermetallic insulating layer 15 disposed on the lower insulating layer 9. In another example embodiment, the first structure 3 may be substituted with the first structure 403 illustrated in FIG. 15B.

At least one buffer insulating layer 21 may be formed on the first structure 3. The at least one buffer insulating layer 21 may include the first buffer insulating layer 21a and the second buffer insulating layer 21b sequentially stacked. The first and second buffer insulating layers 21a and 21b may include different insulating materials.

The first insulating layer 24 having the opening 28 may be formed (S10). The opening 28 may be formed in a plural form, and a plurality of openings 28 may be parallel to each other and spaced apart from each other. Hereinafter, one opening 28 will be mainly described. The first insulating layer 24 may be referred to as an interlayer insulating layer.

The first insulating layer 24 may be formed on the at least one buffer insulating layer 21. The opening 28 may expose the at least one buffer insulating layer 21.

A mask layer 26 may be formed on the first insulating layer 24. The mask layer 26 may be formed before forming the opening 28. Accordingly, the opening 28 may be formed in a shape penetrating through the mask layer 26 and the first insulating layer 24.

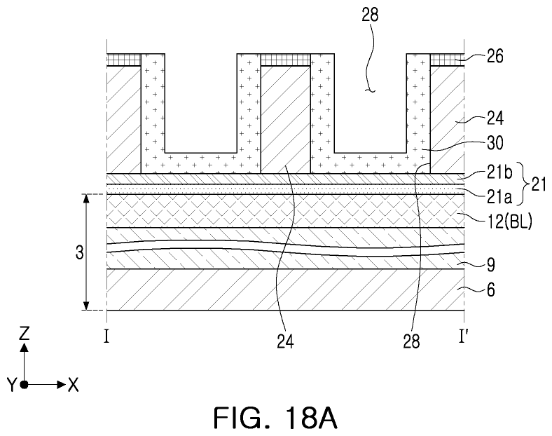

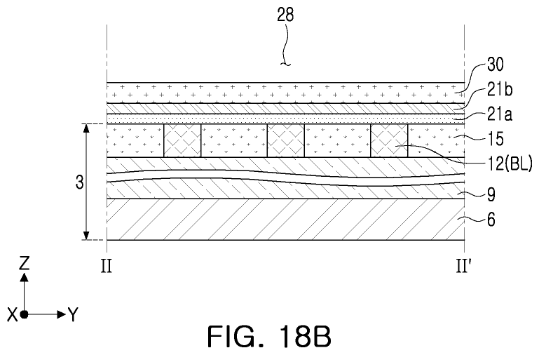

Referring to FIGS. 16, 18A, and 18B, a preliminary gate electrode 30 covering an internal wall of the opening 28 may be formed (S20). The formation of the preliminary gate electrode 30 may include forming a conductive layer for conformally covering the internal wall of the opening 28 and an upper surface of the mask layer 26, forming a sacrificial layer filling the opening 28 on the conductive layer, forming a conductive layer remaining on the internal wall of the opening 28 by etching the conductive layer disposed on the upper surface of the mask layer 26, and removing the sacrificial layer

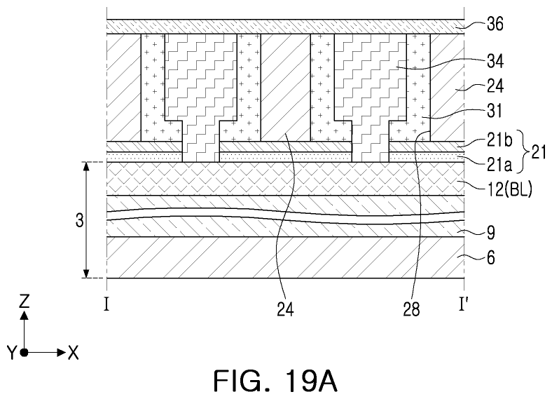

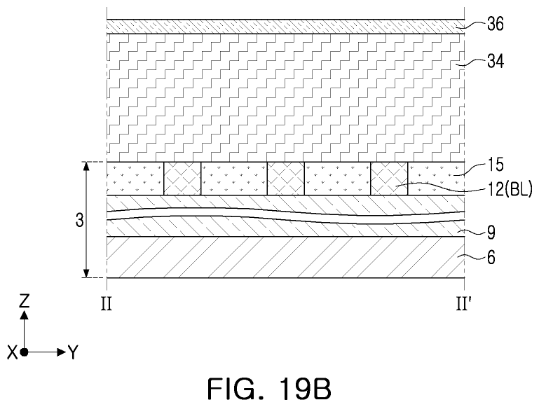

Referring to FIGS. 16, 19A, and 19B, the preliminary gate electrode 30 (see FIG. 18A) may be patterned to form the gate electrodes 31 (S30). The formation of the gate electrodes 31 (see FIG. 19A) by patterning the preliminary gate electrode 30 (see FIG. 18A) may include forming mask spacers on sidewalls of the opening 28 on the preliminary gate electrode 30 (see FIG. 18A), exposing the conductive line 12 by etching the preliminary gate electrode 30 (see FIG. 18A) and simultaneously etching the at least one buffer insulating layer 21 using the mask spacers as etch masks, and removing the mask spacers. Accordingly, the gate electrodes 31 spaced apart from each other may be formed in one opening 28.

The sacrificial material layer 34 may be formed and planarized until the upper surface of the interlayer insulating layer 24 is exposed. The sacrificial material layer 34 may fill the opening 28 in which the gate electrodes 31 are formed. A preliminary etch stop layer 36 may be formed on the sacrificial material layer 34, the gate electrodes 31, and the first insulating layer 24. The preliminary etch stop layer 36 may be formed of an insulating material. For example, the preliminary etch stop layer 36 may be formed of an insulating material, e.g., silicon nitride, SiBN, SiCN, or insulating metal oxide.

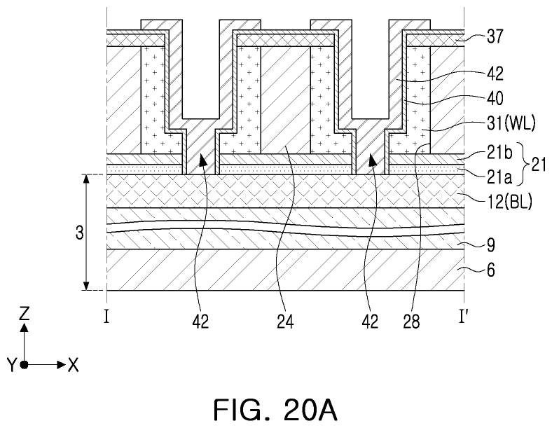

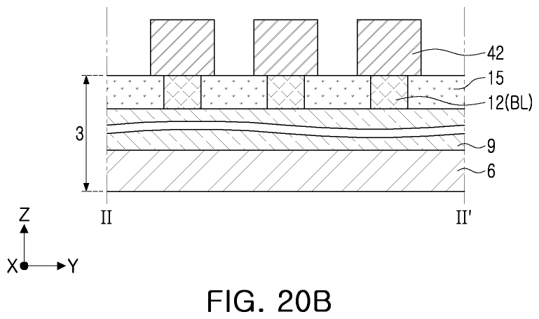

Referring to FIGS. 16, 20A and 20B, the preliminary etch stop layer 36 may be patterned to form an etch stop layer 37 and the sacrificial material layer 34 may be removed. Accordingly, the etch stop layer 37 covering the first insulating layer 24 and the gate electrodes 31 may be formed (S40).

A dielectric layer 40 that conformally covers the gate electrodes 31 and the etch stop layer 37 may be formed. The dielectric layer 40 may be a gate dielectric layer as illustrated in FIG. 2A. In another example, the dielectric layer 40 may be formed of the data storage layer 140 as described in FIG. 7A. Accordingly, a gate dielectric layer or a data storage layer may be formed (S50). In the dielectric layer 40, a portion in contact with the conductive line 12 may be patterned and removed.

The active pattern 42 may be formed (S60). The formation of the active pattern 42 may include forming a preliminary active layer on the dielectric layer 40 and patterning the preliminary active layer.

The active pattern 42 may be formed in the same shape as the active pattern 42 illustrated in FIGS. 1, 2A and 2B. For example, the active pattern 42 may include the first active portion 46C1 disposed adjacent to the first gate electrode 31_1, the second active portion 46C2 disposed adjacent to the second gate electrode 31_2, and the lower active portion 46P extending from the first and second active portions 46C1 and 46C2, as in FIG. 2A. As illustrated in FIG. 2A, the first active portion 46C1 (see FIG. 2A) may include the first vertical active portion 46V1, the first upper bend portion 46E1a bent from the upper region of the first vertical active portion 46V1 in a direction moving away from the second active portion 46C2, and a first lower bend portion 46E1b bent from the lower region of the first vertical active portion 46V1 in a direction approaching the second active portion 46C2, and the second active portion 46C2 (see FIG. 2A) may include the second vertical active portion 46V2, the second upper bend portion 46E2a bent from the upper region of the second vertical active portion 46V2 in a direction moving away from the first active portion 46C1, and the second lower bend portion 46E2b bent from the lower region of the second vertical active portion 46V2 in a direction approaching the first active portion 46C1. In another example, the active pattern 42 may be formed as an active pattern 42′ (see FIG. 3) as illustrated in FIG. 3.

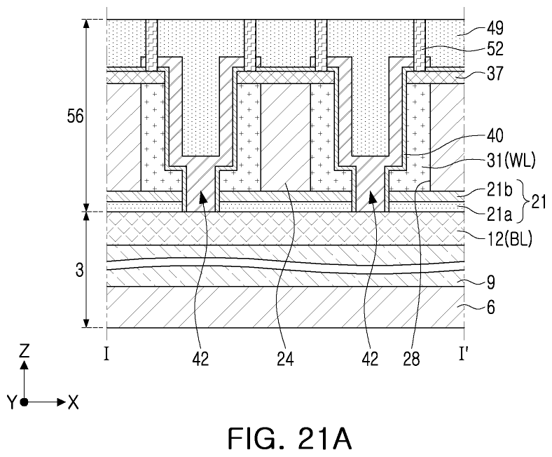

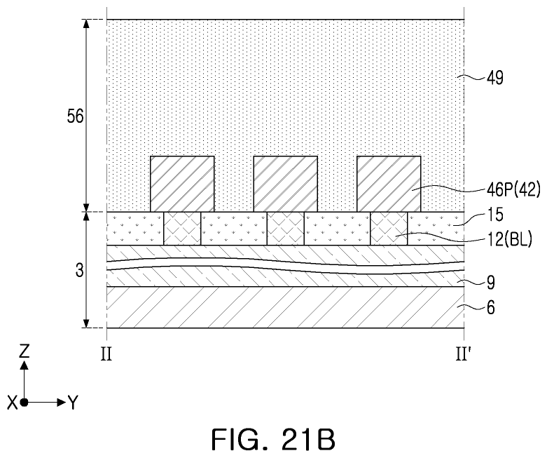

Referring to FIGS. 16, 21A, and 21B, the second insulating layer 49 may be formed (S70). The second insulating layer 49 may be referred to as an upper insulating layer. The second insulating layer 49 may cover the active pattern 42 and fill the opening 28.

The contact plugs 52 may be formed (S80). The formation of the contact plugs 52 may include forming contact holes penetrating the second insulating layer 49, the first and second upper bend portion 46E1a and 46E2a (see FIG. 2A) of the active pattern 42 and the dielectric layer 40, and exposing the etch stop layers 37, and forming a conductive material filling the contact holes. Accordingly, the second structure 56 as illustrated in FIGS. 2A and 2B may be formed.

In an example embodiment, a process margin for forming the contact holes may be improved by forming the etch stop layers 37. The etch stop layers 37 may serve to form a constant distance between the contact plugs 52 and the gate electrodes 31. Since the distance between the contact plugs 52 and the gate electrodes 31 may be formed to be constant (e.g., uniform) by the etch stop layers 37, scattering characteristics of a semiconductor devices may be improved.

Referring again to FIGS. 1, 2A, and 2B, the third structure 70 may be formed on the second structure 56.

In one example, the formation of the third structure 70 may include forming the upper etch stop layer 58, forming first electrodes 64 penetrating the upper etch stop layer 58 and electrically connected to the contact plugs 52, forming a dielectric layer 66 covering the first electrodes 64 and the upper etch stop layer 58, and forming a second electrode 68 covering the dielectric layer 66. The first electrodes 64, the dielectric layer 66, and the second electrode 68 may constitute a data storage structure 61.

In another example, as illustrated in FIGS. 6, 7A and 7B, the formation of the third structure 70 may include forming upper conductive lines 173 (see FIGS. 6, 7A and 7B) electrically connected to the contact plugs 52, and forming a capping insulating layer 176 covering the upper conductive lines 173 (see FIGS. 6, 7A and 7B).

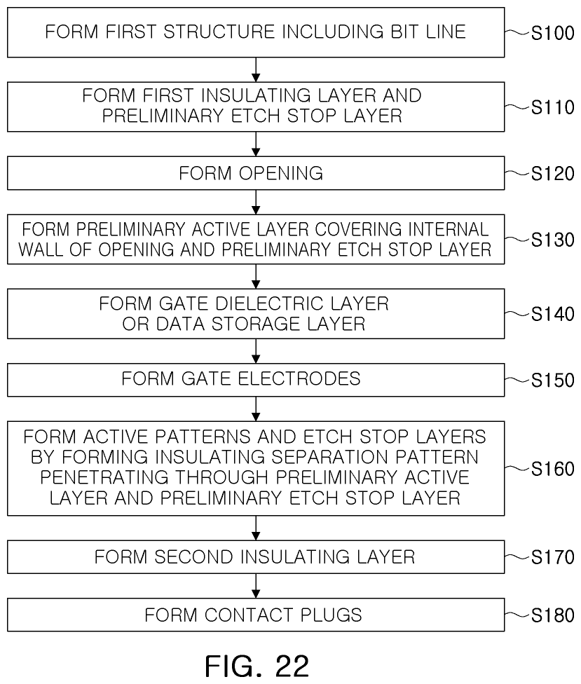

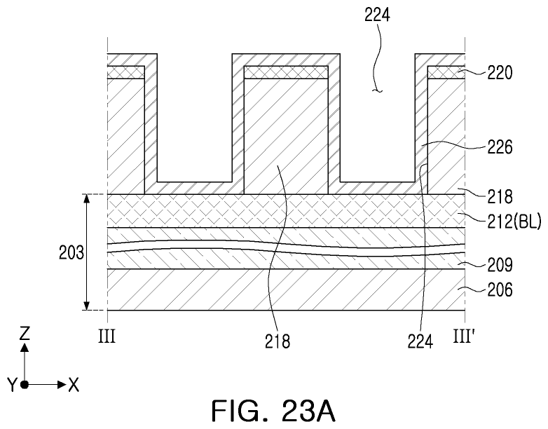

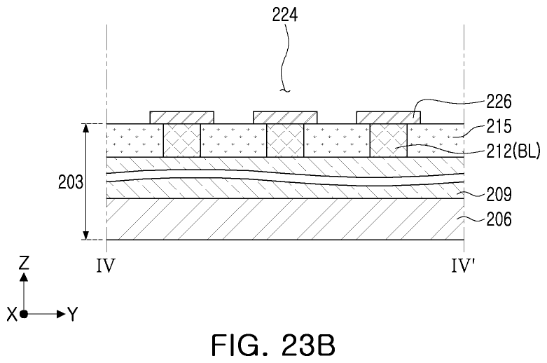

Next, an example of a method of forming a semiconductor device according to example embodiments will be described with reference to FIGS. 22 and 23A to 26B. FIG. 22 is a schematic process flowchart illustrating another example of a method of forming a semiconductor device according to example embodiments, FIGS. 23A, 24A, 25A and 26A are cross-sectional views schematically illustrating a region taken along line III-III′ of FIG. 9, and FIGS. 23B, 24B, 25B and 26B are cross-sectional views schematically illustrating a region taken along line IV-IV′ of FIG. 9.

Referring to FIGS. 22, 23A and 23B, the first structure 203 including the bit line BL may be formed (S100). The first structure 203 may be the first structure 203 as illustrated in FIGS. 10A and 10B. For example, the first structure 203 may include the base 206, the lower insulating layer 209, the conductive lines 212, and the intermetallic insulating layer 215, as described in FIGS. 10A and 10B. The conductive lines 212 may be bit lines BL.

The first insulating layer 218 and the preliminary etch stop layer 220 may be formed (S110). The first insulating layer 218 may be an interlayer insulating layer. The first insulating layer 218 may include silicon oxide or a low-κ dielectric. The preliminary etch stop layer 220 may be formed on the first insulating layer 218. The preliminary etch stop layer 220 may be formed of a conductive material. For example, the preliminary etch stop layer 220 may include doped polysilicon, a metal, a conductive metal nitride, a metal-semiconductor compound, a conductive metal oxide, conductive graphene, carbon nanotubes, or combinations thereof.

The opening 224 may be formed (S120). The opening 224 may penetrate through the preliminary etch stop layer 220 and the first insulating layer 218 to expose the bit line BL.

The opening 224 may be formed in a plural form and a plurality of openings 224 may be spaced apart from each other. Hereinafter, one opening 224 will be mainly described.

A preliminary active layer 226 covering an internal wall of the opening 224 and an upper surface of the preliminary etch stop layer 220 may be formed (S130). The preliminary active layer 226 may be in contact with the bit line BL while covering a side surface and a bottom surface of the opening 224.

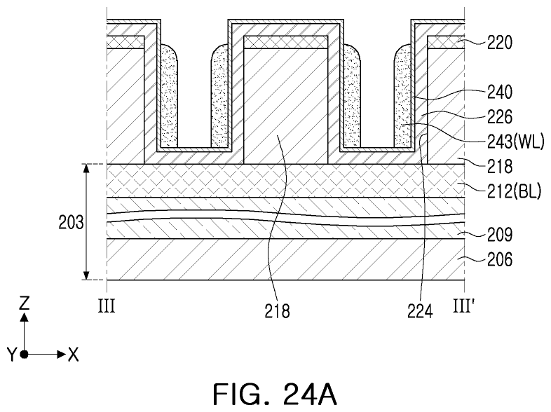

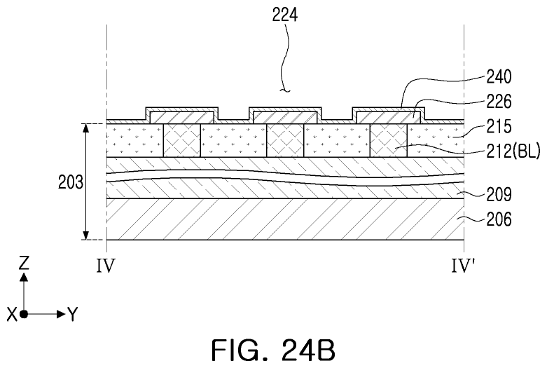

Referring to FIGS. 22, 24A and 24B, the dielectric layer 240 may be formed. The dielectric layer 240 may conformally cover a surface of the preliminary active layer 226. The dielectric layer 240 may be a gate dielectric layer as illustrated in FIG. 10A. In another example, the dielectric layer 240 may be formed of the data storage layer 340 as illustrated in FIG. 14A. Accordingly, a gate dielectric layer or a data storage layer may be formed (S140).

The gate electrodes 243 may be formed (S150). The gate electrodes 243 may be word lines WL. The formation of the gate electrodes 243 may include forming a conductive material layer conformally covering the dielectric layer 240, and forming conductive patterns remaining in the opening 224 by anisotropic etching of the conductive material layer. Here, the conductive patterns remaining in the opening 224 may be the gate electrodes 243.

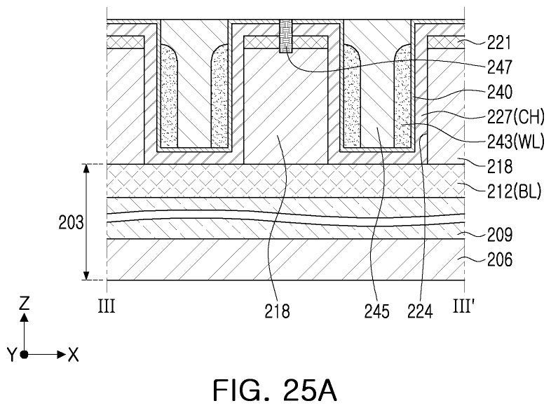

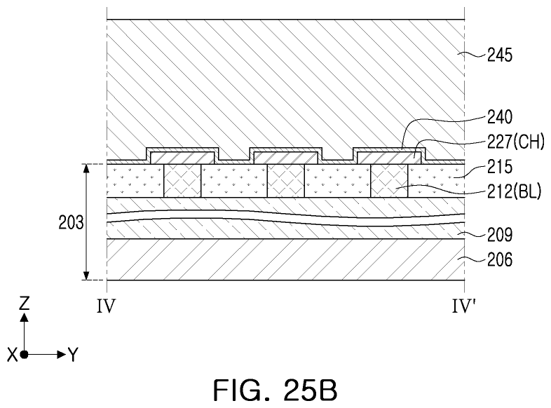

Referring to FIGS. 22, 25A and 25B, a gap fill insulating layer 245 filling the opening 224 may be formed on the dielectric layer 240 and the gate electrodes 243. The gap fill insulating layer 245 may be formed of silicon oxide or a low-κ dielectric material.

An insulating separation pattern 247 penetrating through the preliminary active layer 226 (see FIG. 24A) and the preliminary etch stop layer 220 (see FIG. 24A) may be formed to form active patterns 227 and etch stop layers 221 (S160). The insulating separation pattern 247 may penetrate through the dielectric layer 240 on the preliminary etch stop layer 220 (see FIG. 24A). The insulating separation pattern 247 may be formed on the first insulating layer 218, and may penetrate through the dielectric layer 240, the preliminary active layer 226 (see FIG. 24A), and the preliminary etch stop layer 220 (see FIG. 24A). The insulating separation pattern 247 may be formed of an insulating material, e.g., silicon oxide or silicon nitride.

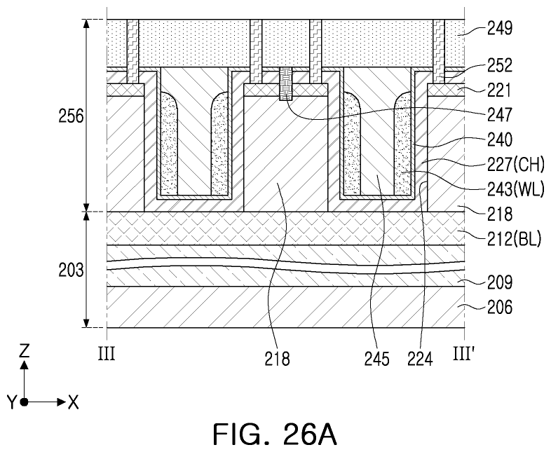

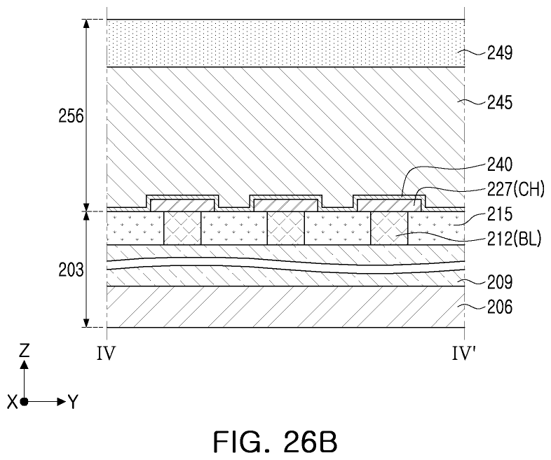

Referring to FIGS. 22, 26A and 26B, a second insulating layer 249 may be formed (S170). The second insulating layer 249 may cover the dielectric layer 240, the insulating separation pattern 247, and the gap fill insulating layer 245. The second insulating layer 249 may be formed of silicon oxide or a low-κ dielectric material. The contact plugs 252 may be formed (S180). The formation of the contact plugs 252 may include forming contact holes penetrating the second insulating layer 249, the dielectric layer 240 and the active pattern 227 and exposing the etch stop layers 221, and forming a conductive material filling the contact holes. Accordingly, the second structure 256 as illustrated in FIGS. 10A and 10B may be formed.

In an example embodiment, by forming the etch stop layers 221, a process margin for forming the contact holes may be improved.

Again, referring to FIGS. 9, 10A and 10B, a third structure 270 may be formed on the second structure 256.

In one example, the formation of third structure 270 may include forming the upper etch stop layer 258, forming first electrodes 264 penetrating through the upper etch stop layer 258 and electrically connected to the contact plugs 252, forming a dielectric layer 266 covering the first electrodes 264 and the upper etch stop layer 258, and forming a second electrode 268 covering the dielectric layer 266. The first electrodes 264, the dielectric layer 266, and the second electrode 268 may constitute a data storage structure 261.

In another example, as illustrated in FIGS. 13, 14A and 14B, the formation of third structure 270 may include forming upper conductive lines 373 (see FIGS. 13, 14A and 14B) electrically connected to the contact plugs 252, and forming a capping insulating layer 376 covering the upper conductive lines 373 (see FIGS. 13, 14A and 14B).

The etch stop layers 221 may serve to maintain a constant distance between the contact plugs 252 and the gate electrodes 243. The distance between the contact plugs 252 and the gate electrodes 243 may remain constant by the etch stop layers 221, thereby improving the scattering characteristics of the semiconductor device. The etch stop layers 221 may prevent an electrical short between the contact plugs 252 and the gate electrodes 243, thereby improving the reliability of the semiconductor device.

According to example embodiments of the present disclosure, a semiconductor device including an etch stop layer configured to form a constant distance between a contact plug and a gate electrode may be provided. By adjusting a thickness of the etch stop layer, the contact plug and the gate electrode may be spaced apart from each other by a desired distance, thereby improving scattering characteristics of the semiconductor device.

According to example embodiments of the present disclosure, the etch stop layer may serve to prevent an electrical short between the contact plug and the gate electrode. Accordingly, the etch stop layer that may prevent an electrical short between the contact plug and the gate electrode may be provided to improve the reliability of the semiconductor device.

By way of summation and review, example embodiments provide a semiconductor device configured to improve scattering characteristics. Example embodiments provide a semiconductor device configured to improve reliability. Example embodiments provide a method of forming a semiconductor device with improved reliability and scattering characteristics.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor device, comprising:
an active pattern including a vertical active portion and a first bend portion, the vertical active portion extending in a vertical direction, and the first bend portion being bent from an upper region of the vertical active portion;
a gate electrode spaced apart from the active pattern, at least a portion of the gate electrode facing the vertical active portion;
an etch stop layer at least between an upper surface of the gate electrode and the first bend portion;
a dielectric layer at least between the active pattern and the gate electrode; and
a contact plug on the etch stop layer, the contact plug penetrating at least through the first bend portion.

2. The semiconductor device as claimed in claim 1, wherein the contact plug is in contact with the first bend portion and the etch stop layer.

3. The semiconductor device as claimed in claim 1, wherein the first bend portion surrounds a side surface of the contact plug and is in contact with the contact plug.

4. The semiconductor device as claimed in claim 1, further comprising:
a bit line; and
at least one buffer insulating layer on the bit line,
wherein:
the gate electrode includes a vertical gate portion facing the vertical active portion and a horizontal gate portion extending from a lower region of the vertical gate portion,
the horizontal gate portion and the vertical gate portion are on the at least one buffer insulating layer,
the active pattern further includes a second bend portion that is bent from a lower region of the vertical active portion and a lower active portion extending downward from the second bend portion, the lower active portion penetrating through the at least one buffer insulating layer and being electrically connected to the bit line, and
a direction in which the first bend portion is bent from the upper region of the vertical active portion is different from a direction in which the second bend portion is bent from the lower region of the vertical active portion.

5. The semiconductor device as claimed in claim 4, wherein the at least one buffer insulating layer includes a first buffer insulating layer and a second buffer insulating layer sequentially stacked, a material of the first buffer insulating layer being different from a material of the second buffer insulating layer.

6. The semiconductor device as claimed in claim 1, further comprising a data storage structure electrically connected to the contact plug and on the contact plug.

7. The semiconductor device as claimed in claim 1, further comprising a conductive pattern electrically connected to the contact plug and on the contact plug,
wherein the dielectric layer includes a data storage layer.

8. The semiconductor device as claimed in claim 7, wherein the dielectric layer includes a ferroelectric layer.

9. The semiconductor device as claimed in claim 1, wherein:
the active pattern further includes a second bend portion that is bent from a lower region of the vertical active portion,
the first bend portion is bent in a first direction from the upper region of the vertical active portion, and
the second bend portion is bent in a second direction different from the first direction from the lower region of the vertical active portion.

10. The semiconductor device as claimed in claim 1, wherein:
the dielectric layer extends continuously between the active pattern and the gate electrode, and further extends between the active pattern and the etch stop layer,
the first bend portion of the active pattern is spaced apart from the etch stop layer by the dielectric layer,
the contact plug extends downward through the first bend portion and the dielectric layer, and
the contact plug is in contact with the first bend portion, the dielectric layer, and the etch stop layer.

11. The semiconductor device as claimed in claim 1, wherein:
the active pattern includes a first active layer and a second active layer,
the first active layer is between the gate electrode and the second active layer, and between a side surface of the etch stop layer and the second active layer,
the second active layer includes the first bend portion,
the first bend portion of the second active layer is in contact with the etch stop layer,
the first active layer is spaced apart from the etch stop layer by the dielectric layer,
the contact plug penetrates through the first bend portion of the second active layer and is in contact with the second active layer, and
the contact plug is spaced apart from the first active layer.

12. A semiconductor device, comprising,
a bit line;
an active pattern electrically connected to the bit line;
a word line at a same level as at least a first portion of the active pattern;
a dielectric layer at least between the active pattern and the word line;
an etch stop layer having a portion at a same level as a second portion of the active pattern, and an upper end of the active pattern being at a higher level than a lower surface of the etch stop layer; and
a contact plug in contact with the etch stop layer on the etch stop layer and electrically connected to the active pattern, a lower surface of the contact plug being at a higher level than the lower surface of the etch stop layer.

13. The semiconductor device as claimed in claim 12, wherein the contact plug is in contact with the active pattern and the etch stop layer, the active pattern being directly and electrically connected to the contact plug.

14. The semiconductor device as claimed in claim 12, wherein:
the contact plug is in contact with the etch stop layer and is spaced apart from the active pattern,
the etch stop layer is in contact with the active pattern,
the etch stop layer includes a conductive material, and
the active pattern is electrically connected to the contact plug by the etch stop layer.

15. The semiconductor device as claimed in claim 12, wherein:
the active pattern includes a vertical active portion and a bend portion that is bent from an upper region of the vertical active portion and vertically overlapping the etch stop layer,
at least a portion of the vertical active portion faces the word line, and
the contact plug penetrates through the bend portion and is in contact with the bend portion.

16. A semiconductor device, comprising:
a bit line;
an interlayer insulating layer on the bit line and having an opening;
a first gate electrode and a second gate electrode spaced apart from each other, in the opening;
an active pattern between the first gate electrode and the second gate electrode, the active pattern being electrically connected to the bit line;
a first etch stop layer on the first gate electrode;
a second etch stop layer on the second gate electrode;
a first dielectric layer at least between the first gate electrode and the active pattern;
a second dielectric layer at least between the second gate electrode and the active pattern;
a first contact plug in contact with the first etch stop layer and on the first etch stop layer; and
a second contact plug in contact with the second etch stop layer and on the second etch stop layer.

17. The semiconductor device as claimed in claim 16, wherein:
a lower surface of the first etch stop layer is in contact with an upper surface of the first gate electrode,
a lower surface of the second etch stop layer is in contact with an upper surface of the second gate electrode,
the first dielectric layer extends continuously between the first etch stop layer and the active pattern, and between the first gate electrode and the active pattern, and
the second dielectric layer extends continuously between the second etch stop layer and the active pattern, and between the second gate electrode and the active pattern.

18. The semiconductor device as claimed in claim 16, wherein the active pattern includes:
a first vertical active portion;
a first upper bend portion that is bent from an upper region of the first vertical active portion in a first direction;
a second vertical active portion; and
a second upper bend portion that is bent from an upper region of the second vertical active portion in a second direction opposite to the first direction,
wherein:
the first vertical active portion faces the first gate electrode and the first etch stop layer,
the first upper bend portion vertically overlaps the first gate electrode and the first etch stop layer, and
the second upper bend portion vertically overlaps the second gate electrode and the second etch stop layer.

19. The semiconductor device as claimed in claim 18, wherein:
the first contact plug is in contact with the first upper bend portion while penetrating through the first upper bend portion, and
the second contact plug is in contact with the second upper bend portion while penetrating through the second upper bend portion.

20. The semiconductor device as claimed in claim 16, wherein:
the first gate electrode includes a first vertical gate portion and a first horizontal gate portion extending from a lower region of the first vertical gate portion,
the second gate electrode includes a second vertical gate portion and a second horizontal gate portion extending from a lower region of the second vertical gate portion, and
the active pattern includes a region vertically overlapping the first horizontal gate portion and a region vertically overlapping the second horizontal gate portion.
